(19) United States
(12) Patent Application Publication
(10) Pub. No.: US 2025/0192071 A1
(43) Pub. Date: Jun. 12, 2025

(54) SEMICONDUCTOR PACKAGE

(71) Applicant: SAMSUNG ELECTRONICS CO.,LTD., Suwon-si (KR)

(72) Inventor: Chengjing ZHANG, Suzhou (CN)

(73) Assignee: SAMSUNG ELECTRONICS CO.,LTD., Suwon-si (KR)

(21) Appl. No.: 18/667,670

(22) Filed: May 17, 2024

(30) Foreign Application Priority Data
Dec. 8, 2023 (CN) 20231 1684505.X

(51) Int. Cl. H01L 23/00; H01L 23/498

(52) U.S. Cl. CPC H01L 23/562; H01L 24/81; H01L 23/49833; H01L 24/16; H01L 24/20; H01L 24/48; H01L 24/73; H01L 2224/16225; H01L 2224/211; H01L 2224/48227; H01L 2224/73259; H01L 2224/81121; H01L 2224/81815; H01L 2924/1815

(57) ABSTRACT

A semiconductor package includes a package body including a connection member having a first surface and a second surface opposite the first surface, and at least one semiconductor chip on the first surface of the connection member, a connection terminal on the second surface of the connection member, and connected to the at least one semiconductor chip through the connection member, and at least one magnet in the package body, the at least one magnet arranged to correspond to a warpage profile of the package body and configured to correct warpage of the package body by applying a force to the package body in response to an external magnetic field applied to the semiconductor package.

### CROSS-REFERENCE TO RELATED APPLICATION

This application is based on and claims priority to the Chinese Patent Application No. 202311684505.X, filed on Dec. 8, 2023, in the China National Intellectual Property Administration, the disclosure of which is incorporated by reference herein in its entirety.

### BACKGROUND

Example embodiments of the disclosure relate to a semiconductor package, particularly, relates to a semiconductor package and a manufacturing method thereof.

In order to achieve more integrated functions, a plurality of semiconductor devices may be packaged to form a semiconductor package. The packaged semiconductor package may be electrically connected to an external substrate (e.g., a printed circuit board (PCB)) through connection terminals such as solder balls, etc. However, the semiconductor package may warp easily due to the material characteristic and structure characteristic thereof. For example, due to differences between coefficients of thermal expansion (CTE) of respective components of the semiconductor package, the semiconductor package may warp while undergoing a heat treatment.

For example, in performing a surface mounting technology (SMT) process for electrically connecting the semiconductor package and the external substrate, the connection terminals of the semiconductor package may undergo reflow soldering to be coupled to connection pads of the external substrate. Under a high-temperature condition of the reflow soldering, a warpage (i.e., a high-temperature warpage) may occur in the semiconductor package. When the high-temperature warpage occurs in the semiconductor package, there may be a mismatch between the semiconductor package and the external substrate due to the high-temperature warpage, such that the connection terminals of the semiconductor package may not effectively wet the connection pads of the external substrate during the reflow soldering (i.e., non-wetting occurs), which causes electrical connection defects, such as non-soldering or virtual soldering, etc., between the connection terminals and the connection pads.

In addition, as the decrease of a vertical size (e.g., a height) and/or the increase of a horizontal size (e.g., a length, a width, and/or an area) of the semiconductor package and/or the diversity of the components included in the semiconductor package, a degree of the high-temperature warpage of the semiconductor package increases, and a profile of the high-temperature warpage of the semiconductor package becomes increasingly complex, which makes the control for the high-temperature warpage of the semiconductor package more challenging.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package having suppressed or reduced warpage.

One or more example embodiments provide a semiconductor package having improved electrical connection with an external substrate.

Additional aspects will be set forth in part in the description which follows and, in part, will be apparent from the description, or may be learned by practice of the presented embodiments.

According to an aspect of an example embodiment, a semiconductor package may include a package body including a connection member having a first surface and a second surface opposite the first surface, and at least one semiconductor chip on the first surface of the connection member, a connection terminal on the second surface of the connection member, and connected to the at least one semiconductor chip through the connection member, and at least one magnet in the package body, the at least one magnet arranged to correspond to a warpage profile of the package body and configured to correct warpage of the package body by applying a force to the package body in response to an external magnetic field applied to the semiconductor package.

According to an aspect of an example embodiment, a semiconductor package may include a package body including a connection member having a first surface and a second surface, and at least one semiconductor chip on the first surface of the connection member, at least one first magnet, and at least one second magnet spaced apart from the at least one first magnet, where, in response to an external magnetic field being applied to the package body, the at least one first magnet is configured to apply a first force to the package body in a first direction, and the at least one second magnet is configured to apply a second force to the package body in a second direction that is different from the first direction.

According to an aspect of an example embodiment, a method may include providing a semiconductor package including a package body including a connection member having a first surface and a second surface, and at least one semiconductor chip on the first surface of the connection member, at least one connection terminal on the second surface of the connection member, and at least one magnet in the package body, aligning the at least one connection terminal with at least one substrate pad of an external substrate, applying heat to the semiconductor package, and correcting warpage of the package body by applying an external magnetic force to the semiconductor package that causes the at least one magnet in the package body to apply a force to the package body in a direction that is opposite to a direction of the warpage.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more example embodiments;

FIG. 2A is a cross-sectional view illustrating a semiconductor package in which a high-temperature warpage occurs according to one or more example embodiments;

FIG. 2B is a plan view illustrating a semiconductor package in which a high-temperature warpage occurs according to one or more example embodiments;

FIG. 3A is a cross-sectional view illustrating a semiconductor package according to one or more example embodiments;

FIG. 3B is a top view illustrating a semiconductor package according to one or more example embodiments;

FIG. 3C is a bottom view illustrating a semiconductor package according to one or more example embodiments;

FIG. 4A through FIG. 4E are cross-sectional views illustrating a surface mounting process of a semiconductor package according to one or more example embodiments;

FIG. 5 is a cross-sectional view illustrating a semiconductor package according to one or more example embodiments;

FIG. 6 is a bottom view illustrating a semiconductor package according to one or more example embodiments;

FIG. 7A is a cross-sectional view illustrating a semiconductor package according to one or more example embodiments;

FIG. 7B is a top view illustrating a semiconductor package according to one or more example embodiments;

FIG. 7C is a bottom view illustrating a semiconductor package according to one or more example embodiments;

FIGS. 8A and 8B are bottom views illustrating a semiconductor package according to one or more example embodiments; and

FIG. 9 is a bottom view illustrating a semiconductor package having a complex high-temperature warpage according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

In the drawings, for the sake of clarity, sizes of an element, a component, a layer, and a region are exaggerated. In the drawings, the same or similar reference numerals denote the same or similar components.

In this specification, the singular forms “a” and “an” are intended to include the plural forms as well, unless the context clearly indicates otherwise. As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that, although terms “first,” “second,” “third,” etc., may be used herein to describe various elements, components, regions, layers and/or sections, these elements, components, regions, layers and/or sections should not be limited by these terms. These terms are used to distinguish one element, component, region, layer, or section from another element, component, region, layer or section. Thus, without departing from the scope of the present disclosure, a first element, component, region, layer, or section described herein may be termed as a second element, component, region, layer, or section.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

For ease of description, spatially relative terms such as “beneath,” “below,” “lower,” “above,” “upper,” etc., may be used herein to describe one element's relationship to other elements as illustrated in the figures. It will be understood that the spatially relative terms are intended to encompass different orientations of the device in use or in operation, in addition to the orientation depicted in the figures. For example, if the device in the figures is turned over, an element described to be “below” or “beneath” another element would then be oriented “above” the other component. Therefore, the term “below” can encompass both an orientation of “above” and “below”. The device may be otherwise oriented (rotated by 90 degrees or at other orientations), and the spatially relative terms used herein should be interpreted accordingly.

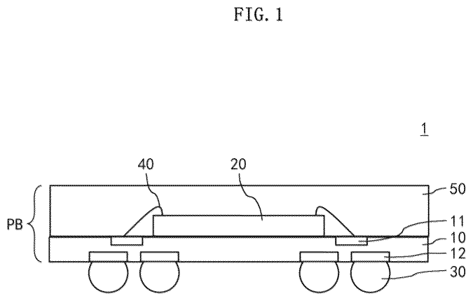

FIG. 1 is a cross-sectional view illustrating a semiconductor package according to one or more example embodiments.

Referring to FIG. 1, a semiconductor package 1 may include a connection member 10 and a semiconductor chip 20 on the connection member 10. The semiconductor chip 20 may be disposed on an upper surface of the connection member 10, and electrically connected to the connection member 10 in a bonding-wire method. In this case, the semiconductor package 1 may further include a bonding wire 40. Further, the connection member 10 may include an upper connection pad 11 exposed at an upper surface thereof, and the semiconductor chip 20 may include a chip pad exposed at an active surface thereof. The active surface of the semiconductor chip 20 may be a surface provided with the chip pad. The bonding wire 40 may be connected between the chip pad of the semiconductor chip 20 and the upper connection pad 11 of the connection member 10, such that the semiconductor chip 20 is electrically connected to the connection member 10. The bonding wire 40 may be formed of a metal (e.g., gold).

The semiconductor package 1 may further include a mold layer 50. The mold layer 50 may be disposed on the upper surface of the connection member 10 provided with the semiconductor chip 20, to encapsulate the semiconductor chip 20. When the semiconductor chip 20 is electrically connected to the connection member 10 in the bonding-wire method, the mold layer 50 may also surround or encapsulate the bonding wire 40. The mold layer 50 may be formed of a molding material, such as an epoxy molding compound (EMC). The connection member 10 may further include a lower connection pad 12 exposed at a lower surface thereof. The lower connection pad 12 of the connection member 10 may be electrically connected to the upper connection pad 11 of the connection member 10 through an internal wiring of the connection member 10, so as to be electrically connected to the semiconductor chip 20 connected with the upper connection pad 11.

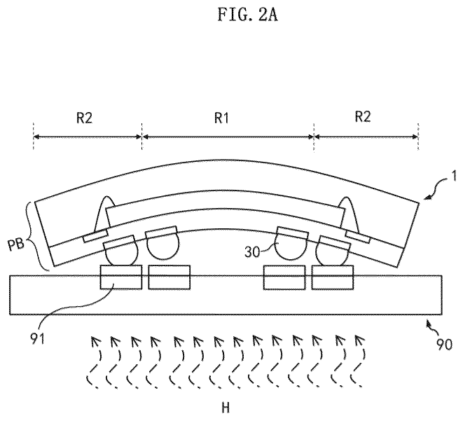

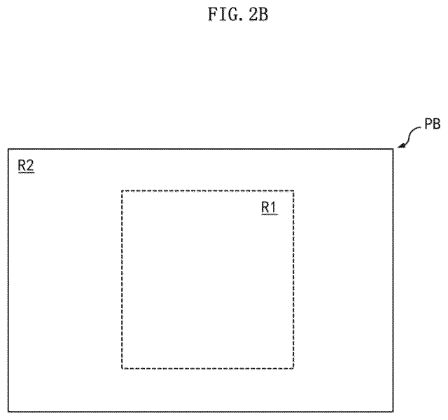

The semiconductor package 1 may further include a connection terminal 30 connected to the lower connection pad 12. The connection terminal 30 may be disposed on an exposed surface of the lower connection pad 12. In the semiconductor package 1, the connection terminal 30 may be electrically connected to the semiconductor chip 20 via the lower connection pad 12 and the upper connection pad 11 that are electrically connected to each other, and be used to electrically connect the semiconductor package 1 (e.g., the semiconductor chip 20) to the outside. For example, in the case where the semiconductor package 1 is mounted on an external substrate (e.g., an external substrate 90 in FIG. 2A), such as a printed circuit board (PCB), an interposer substrate, etc., the connection terminal 30 may be connected to a trace or a substrate pad of the external substrate, to electrically connect the semiconductor package 1 and the external substrate. The upper connection pad 11 and the lower connection pad 12 of the connection member 10 may be formed of a metal (e.g., copper, aluminum, tungsten, etc.).

The connection terminal 30 may include or may be a solder ball, and may be formed of solder. The semiconductor package 1 may be attached to the external substrate through a surface mounting technology (SMT). For example, the connection terminal 30 may be coupled to the trace or the substrate pad of the external substrate by performing reflow soldering. However, since the entire semiconductor package 1 is usually under a condition of a relatively high temperature during the reflow soldering, a package body PB including the connection member 10, the semiconductor chip 20, the mold layer 50, etc., of the semiconductor package 1 may also undergo exposure to the high temperature, in addition to the connection terminal 30, and as a result, a high-temperature warpage may occur in the package body PB. The occurrence of the high-temperature warpage may be mainly due to differences in intrinsic characteristics (e.g., material characteristics, structure characteristics, etc.) of the respective components (e.g., the connection member 10, the semiconductor chip 20, and/or the mold layer 50) of the semiconductor package 1, differences in coefficients of thermal expansion (CTE) between the respective components, etc., but not limited thereto.

FIG. 2A is a cross-sectional view illustrating a semiconductor package in which a high-temperature warpage occurs according to one or more example embodiments. FIG. 2B is a plan view illustrating a semiconductor package in which a high-temperature warpage occurs according to one or more example embodiments.

Referring to FIG. 2A, in a reflow soldering process of attaching the semiconductor package 1 to an external substrate 90, heat H may be applied to the semiconductor package 1 and the external substrate 90 that have been aligned with each other. Specifically, the connection terminals 30 of the semiconductor package 1 may be aligned with corresponding substrate pads 91 of the external substrate 90. Then the heat H may be applied to the semiconductor package 1 and the external substrate 90 aligned with each other to perform the reflow soldering process. The connection terminals 30 (e.g., solder balls) of the semiconductor package 1 may be melted by the heat H, and attached to the substrate pads 91 (or traces) of the external substrate 90 through flux that is also melted by the heat H. Afterwards, the application of the heat H may be stopped, and the melted connection terminal 30 and flux may be cooled, so as to complete the reflow soldering process. As such, the semiconductor package 1 and the external substrate 90 may be electrically connected via the connection terminals 30 and the substrate pads 91 that are connected (e.g., soldered) to each other.

As described above, during the reflow soldering process, the high-temperature warpage may occur in the package body PB of the semiconductor package 1 due to the high temperature. The package body PB may have the high-temperature warpage of various profiles due to the high temperature, and may include a plurality of portions having warpages (e.g., high-temperature warpages) along different directions.

Referring to FIGS. 2A and 2B, for example, a profile of the high-temperature warpage of the package body PB may have a curved-surface shape of which the center is warped upward. For example, the profile of the high-temperature warpage of the package body PB may have a convex curved-surface shape in which an edge portion is lower and a center portion is higher. However, depending on differences in the size of the package body PB, the components included in the package body PB, the package form of the package body PB, the process condition of the high-temperature process that the package body PB undergoes, and the like, the high-temperature warpage of the package body PB may also occur in other profiles, which will be described later.

As illustrated in FIG. 2A, the plurality of portions of the package body PB, in which the warpages (e.g., the high-temperature warpages) occur along different directions may include a first portion R1 and a second portion R2. The first portion R1 of the package body PB may be a portion of the package body PB in which an upward warpage occurs, and the second portion R2 of the package body PB may be a portion of the package body PB in which a downward warpage occurs. The term “upward warpage” may refer to an upward displacement or deformation with respect to a position at which the package body PB that does not warp (e.g., that is flat or substantially flat) is located, and the term “downward warpage” may refer to a downward displacement or deformation with respect to the position at which the package body PB that does not warp (e.g., that is flat or substantially flat) is located.

For example, in the cross-sectional view of FIG. 2A, the first portion R1 of the package body PB may be displaced upwardly (e.g., in a direction away from the external substrate 90) with respect to a position at which a corresponding portion of the package body PB that does not warp is located, and the second portion R2 of the package body PB may be displaced downwardly (e.g., in a direction toward the external substrate 90) with respect to a position at which a corresponding portion of the package body PB that does not warp. That is, when the warpage (e.g., the high-temperature warpage) occurs in the package body PB, the first portion R1 of the package body PB may be a portion that warps along a direction away from the external substrate 90, and the second portion R2 of the package body PB may be a portion that warps along a direction toward the external substrate 90. In the package body PB in which the warpage occurs, a distance between the first portion R1 of the package body PB and the external substrate 90 may be greater than a distance between the second portion R2 of the package body PB and the external substrate 90. For example, a minimum distance between the first portion R1 of the package body PB and the external substrate 90 may be greater than a maximum distance between the second portion R2 of the package body PB and the external substrate 90. For example, an average distance between the first portion R1 of the package body PB and the external substrate 90 may be greater than an average distance between the second portion R2 of the package body PB and the external substrate 90.

Further, the first portion R1 of the package body PB may include a plurality of portions (e.g., a plurality of portions continuous with each other) of which degrees of warpage are different, and the second portion R2 of the package body PB may include a plurality of portions (e.g., a plurality of portions continuous with each other) of which degrees of warpage are different. The term “degree of warpage” or “warpage degree” may refer to the amount of displacement or deformation when a warpage (e.g., a high-temperature warpage) occurs as compared to when the warpage (e.g., the high-temperature warpage) does not occur. For example, the degree of warpage (e.g., the degree of high-temperature warpage) of the package body PB may be determined by a change in the distance between the package body PB and the external substrate 90 before and after the warpage (e.g., the high-temperature warpage) occurs. The greater the amount (e.g., an absolute value) of change in the distance between the package body PB and the external substrate 90, the greater the degree of warpage, and the smaller the amount (e.g., the absolute value) of change in the distance, the smaller the degree of warpage.

Referring to FIG. 2B together with FIG. 2A, a top view of the package body PB of which the profile of the high-temperature warpage is in a convex curved-surface shape is illustrated. As illustrated in FIG. 2B, a center portion (i.e., the first portion R1) of the package body PB is warped outward from a plane where the top view of FIG. 2B is, due to the occurrence of the high-temperature warpage, and an edge portion (i.e., the second portion R2) of the package body PB that surrounds the center portion thereof is warped inward from the plane due to the occurrence of the high-temperature warpage. However, this is only an example, and the distribution (e.g., in a plan or a three-dimensional space) of the first portion R1 and the second portion R2 of the package body PB may be in a more complex form when a more complex high-temperature warpage occurs in the package body PB under the high temperature, which will be described later.

Referring again to FIG. 2A, when the warpage (e.g., the high-temperature warpage) occurs in the package body PB, the connection terminals 30 at the first portion R1 of the package body PB become distanced from the external substrate 90 as the first portion R1 becomes distanced from the external substrate 90, such that these connection terminals 30 may not become in contact with the substrate pads 91, resulting in these connection terminals 30 not being connected with the substrate pads 91 of the external substrate 90 (i.e., non-soldering occurs) during the reflow soldering. In addition, the connection terminals at a portion between the first portion R1 and the second portion R2 of the package body PB become distanced from the external substrate 90 to a certain extent as the first portion R1 becomes distanced from the external substrate 90, such that these connection terminals may not become in effective contact with the substrate pads 91 of the external substrate 90, resulting in these connection terminals not being effectively connected with the substrate pads 91 of the external substrate 90 (i.e., virtual soldering occurs). In addition, the connection terminals 30 at the second portion R2 of the package body PB become closer to the external substrate 90 as the second portion R2 becomes closer to the external substrate 90, such that these connection terminals 30 are in excessive contact with the substrate pads 91 of the external substrate 90 due to the distance between the package body PB and the external substrate 90 being too small, resulting in softened or melted connection terminals 30 and/or flux being subjected to an excessive pressure and thereby overflowing laterally. Portions of the connection terminals 30 and/or the flux that overflow laterally may contact an adjacent connection terminal 30 and/or flux, resulting in a short circuit between the connection terminals 30 adjacent to each other.

The above respective cases each cause a problem of reliability of the electrical connection between the semiconductor package 1 and the external substrate 90. Accordingly, in order to reduce or prevent such a problem of reliability, there is a need for a package structure and/or a package method capable of effectively suppressing or reducing a high-temperature warpage that occurs in a semiconductor package when it undergoes a high-temperature process (for example, reflow soldering).

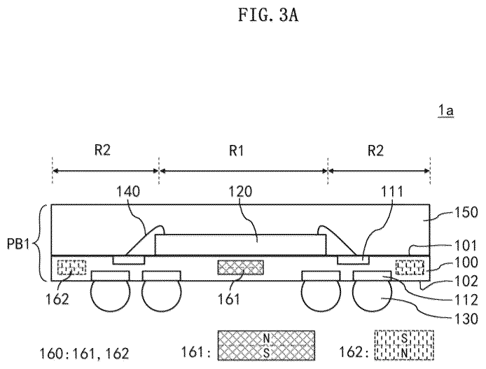

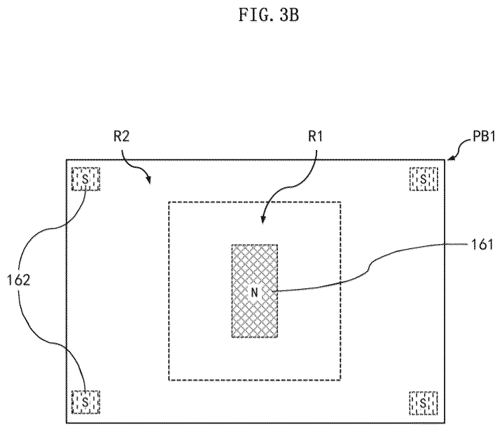

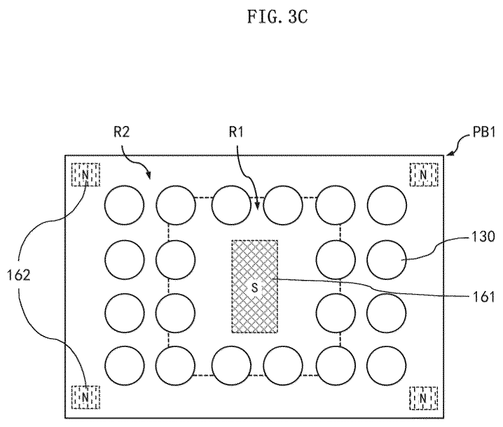

FIG. 3A is a cross-sectional view illustrating a semiconductor package according to one or more example embodiments. FIG. 3B is a top view illustrating a semiconductor package according to one or more example embodiments. FIG. 3C is a bottom view illustrating a semiconductor package according to one or more example embodiments.

Referring to FIG. 3A through FIG. 3C, the semiconductor package 1a according to some embodiments may include a package body PB1, a connection terminal 130, and a magnet 160.

Referring to FIG. 3A, the package body PB1 may include a connection member 100 and a semiconductor chip 120 disposed on the connection member 100. The connection member 100 may have a first surface (e.g., an upper or top surface) 101 and a second surface (e.g., a lower or bottom surface) 102 that are opposite to each other in a thickness direction (e.g., a vertical direction). In some embodiments, the connection member 100 may include or may be a package substrate, such as a PCB, a multi-laminated substrate, or the like. When the connection member 100 includes the package substrate, the connection member 100 may further include an upper connection pad 111 and a lower connection pad 112. The upper connection pad 111 may be disposed in a portion of the connection member 100 adjacent to the first surface 101 and may be exposed via the first surface 101 of the connection member 100, and the lower connection pad 112 may be disposed in a portion of the connection member 100 adjacent to the second surface 102 and may be exposed via the second surface 102 of the connection member 100. However, embodiments are not limited thereto. The upper connection pad 111 and the lower connection pad 112 of the connection member 100 may be correspondingly connected to each other through an internal conductive wiring disposed inside the connection member 100. In some embodiments, the upper connection pad 111, the lower connection pad 112, and the internal conductive wiring of the connection member 100 may include or may be formed of a metal (e.g., aluminum, tungsten, molybdenum, copper, etc.).

The semiconductor chip 120 may be disposed on the first surface 101 of the connection member 100 and electrically connected to the connection member 100. In some embodiments, the semiconductor package 1a may include a plurality of semiconductor chips 120. For example, a plurality of semiconductor chips 120 may be disposed on the first surface 101 of the connection member 100 side by side, and may each be electrically connected to the connection member 100. For example, the plurality of semiconductor chips 120 may be stacked on each other on the first surface 101 of the connection member 100, and each of the plurality of semiconductor chips 120 may be electrically connected to the connection member 100 (for example, electrically connected directly to the connection member 100, or electrically connected to the connection member 100 via at least one other semiconductor chip 120). In some embodiments, the semiconductor chip 120 may be various types of chips, such as at least one of a logic chip (e.g., a central processing unit (CPU), an arithmetic logic unit (ALU), a digital signal processor (DSP), a microcomputer, a field programmable gate array (FPGA), a System-on-Chip, a programmable logic unit, a microprocessor, an application specific integrated circuit (ASIC), etc.) and a memory chip (e.g., a static random access memory (RAM) (SRAM), a dynamic RAM (DRAM), a synchronous dynamic RAM (SDRAM), a flash memory, a phase-change memory, a ferroelectric memory, etc.).

The semiconductor chip 120 may have an active surface and an inactive surface that are opposite to each other in a thickness direction (e.g., a vertical direction). The term “active surface” may refer to a surface of the semiconductor chip provided with a chip pad for the connection to the outside, and the term “inactive surface” may refer to a surface of the semiconductor chip opposite to the active surface. In FIG. 3A, the active surface of the semiconductor chip 120 may be an upper surface or a top surface, and the inactive surface of the semiconductor chip 120 may be a lower surface or a bottom surface. However, embodiments are not limited thereto. As illustrated in FIG. 3A, the semiconductor chip 120 may be disposed on the connection member 100 such that the inactive surface thereof faces the first surface 101 of the connection member 100. The semiconductor chip 120 may be electrically connected with the connection member 100 in a bonding-wire method. The semiconductor package 1a may further include a bonding wire 140, and the bonding wire 140 may be disposed between a chip pad of the semiconductor chip 120 and the upper connection pad 111 of the connection member 100, so as to electrically connect the semiconductor chip 120 to the connection member 100. For example, when the connection member 100 is the package substrate, one end of the bonding wire 140 may be connected to the chip pad of the semiconductor chip 120, and the other end of the bonding wire 140 may be connected to the upper connection pad 111 of the connection member 100.

The package body PB1 may further include a mold layer 150. The mold layer 150 may include or may be formed of a molding material (e.g., EMC). The mold layer 150 may be disposed on the connection member 100 and cover or at least partially cover the semiconductor chip 120. For example, the mold layer 150 may encapsulate the semiconductor chip 120 on the first surface 101 of the connection member 100. As illustrated in FIG. 3A, when the semiconductor package 1a includes the bonding wire 140, the mold layer 150 may also encapsulate the bonding wire 140. In other words, the bonding wire 140 electrically connecting the semiconductor chip 120 and the connection member 100 may extend within and be surrounded by the mold layer 150. In some embodiments, the bonding wire 140 may include or may be formed of a conductive material (e.g., metal). In some embodiments, the bonding wire 140 may be formed with an insulating layer on a surface thereof, and the insulating layer may be interposed between the bonding wire 140 and the mold layer 150.

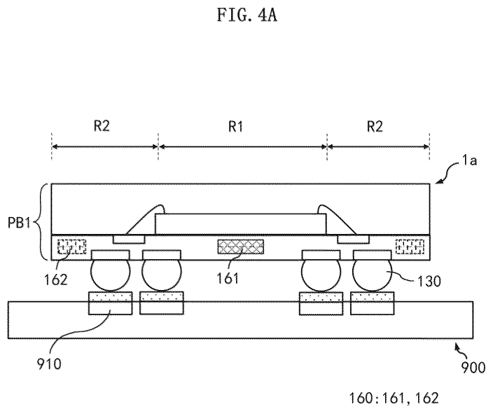

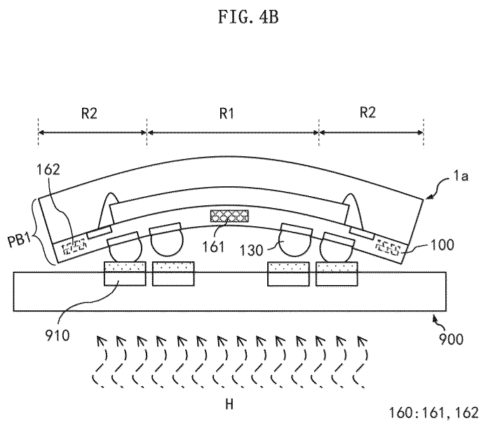

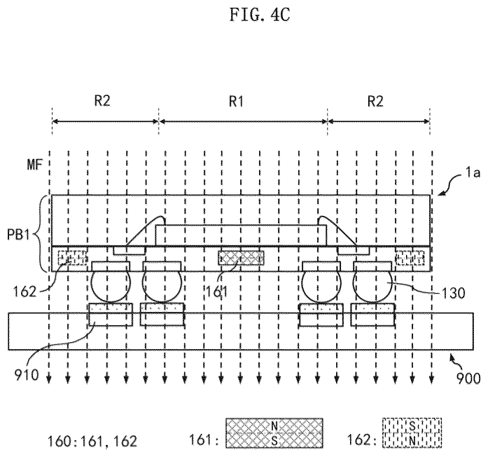

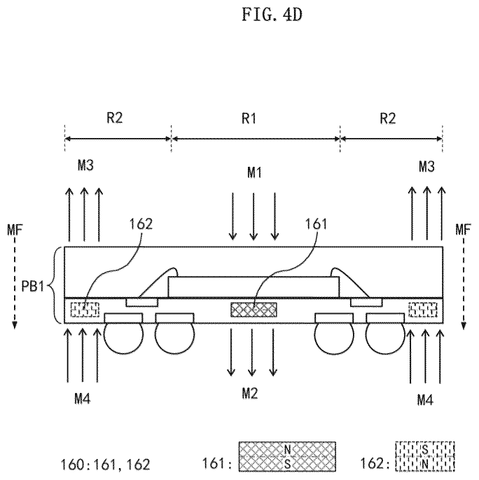

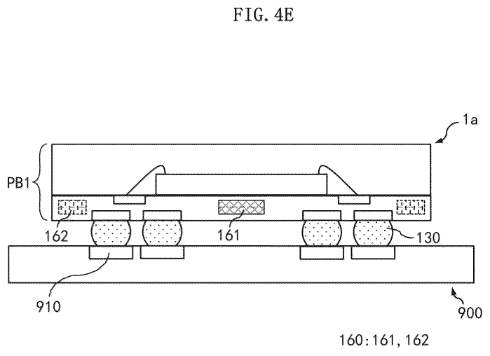

Referring to FIGS. 3A and 3C, the connection terminal 130 (i.e., the plurality of connection terminals 130) may be disposed below the package body PB1. The connection terminal 130 may be electrically connected to the semiconductor chip 120 through the connection member 100. For example, the connection terminal 130 may be disposed on the second surface 102 of the connection member 100. For example, the connection terminal 130 may be a solder ball, and may include or may be formed of solder. For example, the connection terminal 130 may be disposed in a form of a Ball Grid Array (BGA) or a Fine-pitch Ball Grid Array (FBGA), but is not limited thereto. In some embodiments, the connection member 100 may include the package substrate. The connection terminal 130 may be disposed on the lower connection pad 112 of the connection member 100 and connected to the lower connection pad 112 of the connection member 100. The connection terminal 130 may be used to connect the semiconductor package 1a to the outside, for example, to an external substrate 900 illustrated in FIG. 4A.

Referring to FIG. 3A through FIG. 3C, the magnet 160 included in the semiconductor package 1a may be disposed in the package body PB1. The magnet 160 disposed in the package body PB1 may be used to reduce or prevent a warpage of the package body PB1 (e.g., a high-temperature warpage that occurs in the package body PB1 when it undergoes a high-temperature process, such as reflow soldering). The magnet 160 may be distributed in the package body PB1 to correspond to a profile of the warpage which may occur in the package body PB1 (e.g., high-temperature warping), and may be configured to apply a force to the package body PB1 in response to an external magnetic field being applied to the semiconductor package 1a to correct the warpage (e.g., the high-temperature warpage) of the package body PB1.

The magnet 160 may include or may be formed of a magnetic material. In some embodiments, the magnet 160 may have ferromagnetism. For example, the magnet 160 may include or may be formed of a ferromagnetic material. In some embodiments, the magnet 160 may maintain the ferromagnetism under a high-temperature condition (e.g., a temperature condition of reflow soldering). The reflow soldering may generally be performed at a temperature of about 260° C., and accordingly, the magnet 160 according to some embodiments may maintain the ferromagnetism at a temperature of about 260° C. or higher. For example, the magnet 160 may include a material that has a Curie temperature higher than a high temperature (e.g., about 260° C. or higher) to be undergone thereby, such as a magnetic material of neodymium-iron-boron, a magnetic material of ferrite, a magnetic material of samarium-cobalt, a magnetic material of aluminum-nickel-cobalt, or the like. The magnet 160 may generate a force (e.g., a magnetic acting force) in response to an external magnetic field applied to the semiconductor package 1a, and apply the generated force to the package body PB1. Thus, during the high-temperature process (e.g., the reflow soldering), the magnet 160 may use the force (e.g., the magnetic acting force) generated thereby in response to the external magnetic field to correct the high-temperature warpage of the package body PB1. As a result, the high-temperature warpage of the package body PB1 may be corrected (e.g., suppressed, reduced, or eliminated).

Similar to the semiconductor package 1 described above with reference to FIGS. 1, 2A and 2B, a high-temperature warpage having a certain profile may occur in the package body PB1 of the semiconductor package 1a when it undergoes a high-temperature process (e.g., reflow soldering). For example, the profile of the high-temperature warpage of the package body PB1 of the semiconductor package 1a may be in a convex curved-surface shape, a concave curved-surface shape, or other curved-surface shapes having relatively complex undulations (e.g., a wave shape, a saddle shape, etc.). As such, the magnet 160 of the semiconductor package 1a may be configured to be distributed in the package body PB1 in a manner that corresponds to the profile of the high-temperature warpage of the package body PB1 to correct the high-temperature warpage of the package body PB1. For example, in some embodiments, the magnet 160 may be provided in a plurality of groups, and each of the plurality of groups of magnets 160 may be disposed in the package body PB1 to respectively correspond to a plurality of portions, of which profiles of high-temperature warpage (e.g., warpage directions and/or warpage degrees) are different from each other, of the package body PB1.

In some embodiments, when the warpage (e.g., the high-temperature warpage) occurs in the package body PB1 of the semiconductor package 1a, the package body PB1 may have a first portion R1 and a second portion R2 in which warpages (e.g., high-temperature warpages) occur along different directions. For example, the first portion R1 of the package body PB1 may have a first warpage along a first direction, the second portion R2 of the package body PB1 may have a second warpage along a second direction, and the second direction may be different from the first direction. For example, in the case where a high-temperature warpage of a curved-surface shape occurs in the package body PB1 when it undergoes the high-temperature process illustrated in FIG. 3A through FIG. 3C (refer to FIG. 4B), the first portion R1 of the package body PB1 may be a center portion of the package body PB1 that is warped upwardly away from the external substrate 900, and the second portion R2 of the package body PB1 may be an edge portion of the package body PB1 that is warped downward toward the external substrate 900. In this case, the “first direction” may refer to a direction along which the package body is displaced or deformed upwardly after warping as compared to before warping, and the “second direction” may refer to a direction along which the package body is displaced or deformed downwardly after warping as compared to before warping. For example, referring to FIG. 4B, the “first direction” may also refer to a direction along which the package body PB1 becomes distanced from the external substrate 900, and the “second direction” may also refer to a direction along which the package body PB1 becomes nearer to the external substrate 900.

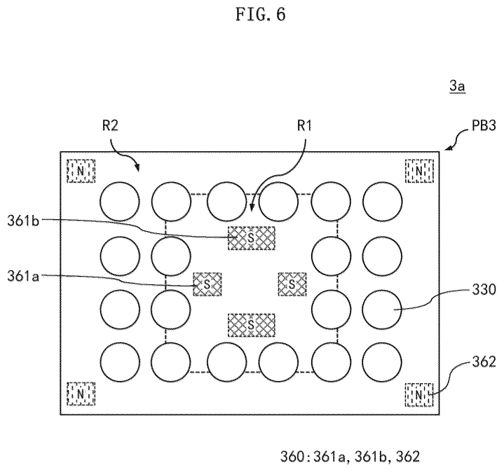

The magnet 160 of the semiconductor package 1a may include a first magnet 161 and a second magnet 162 respectively disposed in the first portion R1 and the second portion R2 of the package body PB1. The first magnet 161 may be configured to correct the warpage of the first portion R1 of the package body PB1, and the second magnet 162 may be configured to correct the warpage of the second portion R2 of the package body PB1. The term “correct” may refer to reducing or eliminating a warpage that occurs in the package body after the package body warped, or may also refer to suppressing a warpage that is to occur in the package body when the package body does not substantively warp but has a tendency to warp. As shown in FIGS. 3B and 3C, the first portion R1 may be defined based on a perimeter of the semiconductor chip 120, and the second portion R2 may be defined as being outside of the perimeter of the semiconductor chip 120. As such, the first magnet 161 may be provided within a perimeter defined by the semiconductor chip 120, and the second magnet 162 may be provided outside of the perimeter defined by the semiconductor chip 120. As further shown in FIG. 3C (as well as FIGS. 6, 7B, 7C, 8A 8B and 9), the first magnet 161 and the second magnet 162 may be provided to as to not overlap with (e.g., to not vertically overlap with) the connection terminals 130.

The first magnet 161 and the second magnet 162 may have magnetic pole orientations different from each other. In some embodiments, the first magnetic pole orientation of the first magnet 161 may correspond to the first direction along which the warpage of the first portion R1 of the package body PB1 occurs, and the second magnetic pole orientation of the second magnet 162 may correspond to the second direction along which the warpage of the second portion R2 of the package body PB1 occurs. As illustrated in FIG. 3A through FIG. 3C, the first magnet 161 and the second magnet 162 may each have a first magnetic pole N and a second magnetic pole S. For example, the first magnet 161 may have the first magnetic pole N oriented upward and the second magnetic pole S oriented downward, while the second magnet 162 may have the second magnetic pole S oriented upward and the first magnetic pole N oriented downward. Thus, the magnetic pole orientation of the first magnet 161 may be different from (e.g., opposite to or substantially opposite to) the magnetic pole orientation of the second magnet 162. Since the first magnetic pole orientation of the first magnet 161 is different from the second magnetic pole orientation of the second magnet 162, a force applied to the package body PB1 by the first magnet 161 has a different direction from that of a force applied to the package body PB1 by the second magnet 162 under the same magnetic field. As a result, the first magnet 161 may be used to correct the warpage along the first direction of the first portion R1 of the package body PB1, and the second magnet 162 may be used to correct the warpage along the second direction of the second portion R2 of the package body PB1. For example, when the first portion R1 of the package body PB1 is warped upward due to the warpage, the first magnet 161 included in the first portion R1 of the package body PB1 may apply a force to the first portion R1 in a direction substantially opposite to the direction along which the first portion R1 is warped upward under the external magnetic field, to correct the warpage of the first portion R1. For example, when the second portion R2 of the package body PB1 is warped downward due to the warpage, the second magnet 162 included in the second portion R2 of the package body PB1 may apply a force to the second portion R2 in a direction substantially opposite to the direction along which the second portion R2 is warped downward under the external magnetic field, to correct the warpage of the second portion R2. As a result, the package body PB1 may be maintained to be flat or substantially flat continuously during the high-temperature process (e.g., the reflow soldering), or the package body PB1 in which the high-temperature warpage already occurs during the high-temperature process (e.g., the reflow soldering) may be recovered to be flat or substantially flat.

A magnitude of the magnetic force of the magnet 160 may be determined according to a degree of the warpage of the package body PB1. For example, the magnetic force (e.g., a magnetic force generated under an external magnetic field) of the magnet 160 may be greater when the degree of the warpage of the package body PB1 is greater, and the magnetic force (e.g., the magnetic force generated under the external magnetic field) of the magnet 160 may be smaller when the degree of the warpage of the package body PB1 is smaller. In other words, the magnetic force of the magnet 160 may be positively correlated with the degree of the warpage of the package body PB1. In the semiconductor package 1a according to some embodiments, the magnetic force generated by the magnet 160 under the external magnetic field may have any suitable magnitude as long as the magnetic force generated by the magnet 160 may correct the warpage (e.g., the high-temperature warpage) of the package body PB1.

The magnetic force of the magnet 160 may be related to properties, such as a size (e.g., an area and/or a volume), a shape, and an inherent magnetic field, of the magnet 160. However, according to example embodiments, the properties, such as the size (e.g., the area and/or the volume), the shape, and the inherent magnetic field, of the magnet 160 are not specifically limited as long as the magnetic force generated by the magnet 160 under the external magnetic field may correct the warpage (e.g., the high-temperature warpage) of the package body PB1.

In some embodiments, referring to FIG. 3A, the first magnet 161 and the second magnet 162 may have substantially the same or similar thicknesses or heights. In some embodiments, referring to FIGS. 3B and 3C, the first magnet 161 may be disposed at a center portion of the first portion R1 of the package body PB1, and the second magnet 162 may be disposed at a corner portion of the second portion R2 of the package body PB1. The first magnet 161 may have a larger area than each of the second magnets 162. When the degree of the warpage (e.g., the upward warpage) of the center portion of the package body PB1 is substantially the same as or similar to the degree of the warpage (e.g., the downward warpage) of the corner portion of the package body PB1, the magnitude of the magnetic force generated by the first magnet 161 under the external magnetic field may be substantially equal to the magnitude of the magnetic force generated by the second magnet 162 under the external magnetic field, even if the first magnet 161 and the second magnet 162 are different from each other in size (e.g., area and/or volume).

Alternatively, the magnitude of the magnetic force of the magnet 160 may be adjusted by controlling (e.g., adjusting) the size (e.g., the area and/or the volume) of the magnet 160. As such, a plurality of magnets 160 capable of exhibiting magnetic forces corresponding to degrees of warpage of respective portions of the package body PB1 may be implemented. Additionally or alternatively, a magnet 160 capable of exhibiting the desired magnetic force may be by adjusting the strength of the inherent magnetic field of the magnet 160. The “inherent magnetic field” may refer to the intrinsic magnetic field that the magnet 160 has when the external magnetic field is not applied.

In addition, the size (e.g., the area and/or the volume) of the magnet 160 may be adjusted according to the degree of freedom of an internal space of the package body PB1. For example, the size of the magnet 160 may be relatively small when the space of the package body PB1 for disposing the magnet 160 is relatively small, and the size of the magnet 160 may be relatively large when the space of the package body PB1 for disposing the magnet 160 is relatively large. That is, the magnets 160 distributed in the package body PB1 may have any suitable size (e.g., area and/or volume) as long as the magnetic force generated by the magnets 160 under the external magnetic field may correct the high-temperature warpage of the package body PB1.

Referring again to FIG. 3A through FIG. 3C, the magnet 160 may be disposed inside the connection member 100. For example, the magnet 160 may be distributed inside the connection member 100 and arranged to correspond to the profile of the warpage which the package body PB1 has in warping. For example, when the package body PB1 includes the first portion R1 and the second portion R2 having warpage along different directions, the magnet 160 may include the first magnet 161 and the second magnet 162 having different magnetic pole orientations, and the first magnet 161 and the second magnet 162 may be disposed inside the connection member 100 in the first portion R1 and the second portion R2, respectively, of the package body PB1. The magnet 160 may be embedded in the connection member 100 during a manufacturing process of the connection member 100. In some embodiments, the connection member 100 may include or may be a package substrate, for example, a PCB or a multi-laminated substrate. For example, the magnet 160 may be formed inside the connection member 100 through a damascene process during a lamination process of forming the connection member 100. For example, the magnet 160 may be embedded in one or more of the laminated layers of the connection member 100, and may be electrically insulated from internal conductive wirings in the connection member 100.

According to example embodiments, the magnet 160 may be disposed in the package body PB1 (e.g., the connection member 100 of the package body PB1) and arranged to correspond to the profile of the warpage of the package body PB1. When undergoing the high-temperature process (e.g., the reflow soldering), the package body PB1 may undergo the high-temperature warpage or have the tendency to undergo the high-temperature warpage. During the high-temperature process (e.g., the reflow soldering), the external magnetic field may be additionally applied to the package body PB1. The magnet 160 in the package body PB1 may apply the force to the package body PB1 under the external magnetic field, and the high-temperature warpage (or the tendency of high-temperature warpage) of the package body PB1 may be corrected (e.g., suppressed, reduced, or eliminated) by the force generated by the magnet 160. As a result, the package body PB1 may maintain flat or substantially flat even undergoing the high-temperature process (e.g., the reflow soldering). Thus, the problem of the high-temperature warpage for the semiconductor package 1a may be effectively improved.

In the above description with reference to FIG. 3A through FIG. 3C, an example of a semiconductor package according to example embodiments is described mainly taking the semiconductor package 1a in which the convex curved-surface shaped warpage occurs. However, example embodiments are not limited thereto. For example, these descriptions may also be equivalently or similarly applied to semiconductor packages having other warpage profiles (e.g., at a high temperature).

A surface mounting process of a semiconductor package according to example embodiments will be described in detail below.

FIG. 4A through FIG. 4E are cross-sectional views illustrating a surface mounting process of a semiconductor package according to one or more example embodiments. Descriptions identical or similar to those given with reference to FIG. 3A through FIG. 3C may be omitted.

Referring to FIG. 4A, a semiconductor package 1a may be prepared. The semiconductor package 1a may include a package body PB1 and a connection terminal 130 disposed on a lower surface of the package body PB1. The package body PB1 may include a first portion R1 and a second portion R2 having high-temperature warpage along different directions when undergoing a high-temperature process (e.g., reflow soldering). The package body PB1 may include a first magnet 161 and a second magnet 162 disposed therein. The first magnet 161 may be disposed in the first portion R1 of the package body PB1, and the second magnet 162 may be disposed in the second portion R2 of the package body PB1. The semiconductor package 1a may be substantially the same as or similar to the semiconductor package 1a described with reference to FIG. 3A through FIG. 3C.

In addition, an external substrate 900 may be prepared. The external substrate 900 may be any suitable type of substrate, for example, but not limited to, a PCB. The external substrate 900 may include a substrate pad 910 disposed in an upper portion thereof and exposed via an upper surface thereof.

After the semiconductor package 1a and the external substrate 900 are prepared, the semiconductor package 1a and the external substrate 900 may be aligned. For example, the semiconductor package 1a may be placed on the external substrate 900 with the connection terminal 130 of the semiconductor package 1a and the substrate pad 910 of the external substrate 900 facing and aligned with each other. For example, the connection terminal 130 of the semiconductor package 1a may contact the substrate pad 910 of the external substrate 900 while facing the substrate pad 910. In some embodiments, a flux for assisting soldering may further be disposed on the substrate pad 910 of the external substrate 900. In this case, the connection terminal 130 of the semiconductor package 1a may face the substrate pad 910 of the external substrate 900, and contact the flux on the substrate pad 910.

Referring to FIG. 4B, after the semiconductor package 1a and the external substrate 900 are aligned, heat H may be applied to perform reflow soldering. For example, the heat H may be applied, such that the connection terminal 130 of the semiconductor package 1a is melted. The melted connection terminal 130 may wet the substrate pad 910, and be coupled with the substrate pad 910. In the example where the flux is further formed on the substrate pad 910 of the external substrate 900, the flux on the substrate pad 910 may also be melted by the heat H, and the melted connection terminal 130 may be fused with the melted flux to be coupled to the substrate pad 910 of the external substrate 900. In this example, because the flux contacts the substrate pad 910 in advance, the wetting of the connection terminal 130 to the substrate pad 910 may be further improved.

However, during the reflow soldering process, a high-temperature warpage may occur in the semiconductor package 1a (e.g., the package body PB of the semiconductor package 1a) due to undergoing a high temperature. As illustrated in FIG. 4B, a high-temperature warpage of a curved-surface shape occurs in the semiconductor package 1a due to undergoing the high-temperature, and thus, the semiconductor package 1a has a first portion R1 warped upward in a direction away from the external substrate 900 and a second portion R2 warped downward in a direction toward to the external substrate 900. Since the first portion R1 of the semiconductor package 1a is warped upward, a distance of the first portion R1 of the semiconductor package 1a from the external substrate 900 is increased, such that a distance of the connection terminals 130 disposed at the first portion R1 of the semiconductor package 1a from the external substrate 900 is increased. As a result, the connection terminals 130 may not contact the substrate pad 910 of the external substrate 900, and may not contact the flux on the substrate pad 910. In addition, since the second portion R2 of the semiconductor package 1a is warped downward, a distance of the second portion R2 of the semiconductor package 1a from the external substrate 900 is decreased, such that a distance of the connection terminals 130 disposed at the second portion R2 of the semiconductor package 1a from the external substrate 900 is decreased. As a result, the connection terminals 130 may overflow laterally toward the space between the semiconductor package 1a and the external substrate 900 due to excessive compression by the package body PB1 and/or the substrate pad 910. In addition, a portion of connection terminals disposed at a portion of the semiconductor package 1a between the first portion R1 and the second portion R2 may not form an effective contact with the substrate pad 910 or the flux due to an improper distance of this portion of the semiconductor package 1a from the external substrate 900. The above respective cases occurring due to the high-temperature warpage of the semiconductor package 1a may each cause electrical connection defects (e.g. non-soldering, virtual soldering or short circuit) between the connection terminal 130 and the substrate pad 910.

Referring to FIG. 4C, an external magnetic field MF may be applied to the semiconductor package 1a during the reflow soldering. For example, the external magnetic field MF may be applied to the package body PB1 of the semiconductor package 1a. For example, the external magnetic field MF may be applied to the package body PB1 from above the semiconductor package 1a along one direction (e.g., a direction from above to below), but is not limited thereto. In some embodiments, the external magnetic field may be applied to the package body PB1 from below the semiconductor package 1a along one direction (e.g., a direction from below to above). In some embodiments, one or more external magnetic fields may be applied to the package body PB1 of the semiconductor package 1a from one or more directions. According to example embodiments, the number and/or directions of the external magnetic fields applied during (or subsequent to) the high-temperature process (e.g. the reflow soldering) may be appropriately determined according to the specific profile of the high-temperature warpage of the package body PB1 and the specific arrangement of the magnet 160 included in the package body PB1, as long as the magnetic force generated by the magnet 160 in the package body PB1 under the external magnetic field(s) may correct the high-temperature warpage of the package body PB1.

Referring to FIG. 4D together with FIGS. 4B and 4C, the magnet 160 may generate a force (e.g., a magnetic acting force) under the external magnetic field MF, and apply the generated force to the package body PB1. The high-temperature warpage of the package body PB1 may be corrected by the force applied by the magnet 160, and the package body PB1 may be recovered into a flat or substantially flat state. In FIG. 4D, the external substrate 900 is omitted for convenience of explanation and illustration.

As illustrated in FIG. 4D, the first magnet 161 included in the first portion R1 of the package body PB1 may generate a first acting force M1 and a second acting force M2 under the external magnetic field MF. In some embodiments, the first magnet 161 may have a first magnetic pole N and a second magnetic pole S. A portion of the first magnet 161 having the first magnetic pole N may generate the first acting force M1 under the external magnetic field MF, and a portion of the first magnet 161 having the second magnetic pole S may generate the second acting force M2 under the external magnetic field MF.

As illustrated in FIG. 4D, the second magnet 162 included in the second portion R2 of the package body PB1 may generate a third acting force M3 and a fourth acting force M4 under the external magnetic field MF. In some embodiments, the second magnet 162 may have a first magnetic pole N and a second magnetic pole S. The first magnetic pole N of the second magnet 162 may have an orientation different from (for example, but not limited to, opposite to) that of the first magnetic pole N of the first magnet 161, and the second magnetic pole S of the second magnet 162 may have an orientation different from (for example, but not limited to, opposite to) that of the second magnetic pole S of the first magnet 161. A portion of the second magnet 162 having the second magnetic pole S may generate the third acting force M3 under the external magnetic field MF, and a portion of the second magnet 162 having the first magnetic pole N may generate the fourth acting force M4 under the external magnetic field MF.

As illustrated in FIG. 4D, when the external magnetic field MF is applied, the first acting force M1 and the second acting force M2 generated by the first magnet 161 may have the same direction, the third acting force M3 and the fourth acting force M4 generated by the second magnet 162 may have the same direction, and the direction of the acting force generated by the first magnet 161 may be different from (for example, but not limited to, opposite to) the direction of the acting force generated by the second magnet 162.

A resultant force of the first acting force M1 and the second acting force M2 generated by the first magnet 161 may cause the first portion R1 that is warped upward (e.g., away from the external substrate 900) of the package body PB1 move downwardly (e.g., toward the external substrate 900), thereby correcting the high-temperature warpage of the first portion R1 of the package body PB1. In this case, the first magnet 161 may apply a first force (i.e., the resultant force of the first acting force M1 and the second acting force M2) to the first portion R1 of the package body PB1 under the external magnetic field MF. The first force may have a direction opposite to or substantially opposite to the warpage direction of the first portion R1 and a magnitude positively correlated with the warpage degree of the first portion R1.

The resultant force of the third acting force M3 and the fourth acting force M4 generated by the second magnet 162 may cause the second portion R2 that is warped downward (e.g., toward the external substrate 900) of the package body PB1 move upwardly (e.g., away from the external substrate 900), thereby correcting the high-temperature warpage of the second portion R2 of the package body PB1. In this case, the second magnet 162 may apply a second force (i.e., the resultant force of the third acting force M3 and the fourth acting force M4) to the second portion R2 of the package body PB1 under the external magnetic field MF. The second force may have a direction opposite to or substantially opposite to the warpage direction of the second portion R2 and a magnitude positively correlated with the warpage degree of the second portion R2.

In some embodiments, one or more external magnetic fields may also be applied to the package body PB1 along one or more directions. In this case, the first acting force M1 and the second acting force M2 generated by the first magnet 161 may have the same or different action directions as or from each other, and/or may have the same or different magnitudes as or from each other. Similarly, the third acting force M3 and the fourth acting force M4 generated by the second magnet 162 may have the same or different directions as or from each other, and/or may have the same or different magnitudes as or from each other. In such embodiments, the resultant force of various acting forces generated by the first magnet 161 under the external magnetic field may correct (e.g., suppress, reduce or eliminate) the warpage of the portion of the package body PB1 provided with the first magnet 161 therein, and the resultant force of various acting forces generated by the second magnet 162 under the external magnetic field may correct (e.g., suppress, reduce or eliminate) the warpage of the portion of the package body PB1 provided with the second magnet 162 therein. That is, the strength and/or direction of the one or more external magnetic fields applied herein may be appropriately determined according to the profile of the warpage of the package body PB1. Further, the one or more external magnetic fields applied herein may be applied asynchronously or synchronously to the package body PB1, and/or may be applied independently or commonly to the first magnet 161 and/or the second magnet 162 of the magnet 160.

Referring to FIG. 4B through FIG. 4D together, the external magnetic field MF may be continuously applied during the reflow soldering. As such, the magnet 160 (e.g., the first magnet 161 and the second magnet 162) may continuously apply the acting force to the package body PB1 under the external magnetic field MF. In the case where the package body PB1 has warped due to the high temperature, the acting force applied to the package body PB1 by the magnet 160 may correct (e.g., reduce or eliminate) the warpage that has occurred in the package body PB1. In the case where the warpage of the package body PB1 has been corrected by the acting force applied to the package body PB1 by the magnet 160, the acting force applied to the package body PB1 by the magnet 160 may be used to correct (e.g., suppress or offset) the warpage tendency of the package body PB1 due to the high-temperature, such that the package body PB1 may maintain a flat or substantially flat profile.

In some embodiments, the external magnetic field MF may be continuously applied until the reflow soldering is completed. For example, the external magnetic field MF may be continuously applied until the semiconductor package 1a is cooled to a predetermined temperature. For example, the predetermined temperature may correspond to a temperature of the semiconductor package 1a when the package body PB1 no longer undergoes a high-temperature warpage or no longer undergoes a tendency of high-temperature warpage, such as the room temperature. In order to complete the reflow soldering, the application of the heat H to the semiconductor package 1a and the external substrate 900 may be stopped, or the amount of the heat H applied to the semiconductor package 1a and the external substrate 900 may be gradually decreased until no more heat H is applied. As such, the melted connection terminal 130 of the semiconductor package 1a may be gradually solidified due to the decrease in temperature, and finally become solid. In some embodiments, when the flux is disposed on the substrate pad 910, the flux on the connection terminal 130 and the substrate pad 910 may be fused with each other under the high-temperature condition and form a new connection terminal by surface tension, and when the heat H is stopped to be applied or the amount of the applied heat H is gradually decreased, the new connection terminal may be gradually solidified due to the decrease in temperature, and finally become solid. As described above, the external magnetic field MF may be continuously applied during the solidification of the connection terminal 130 until the connection terminal 130 is completely solidified. After the connection terminal 130 is solidified, the reflow soldering may be completed. The semiconductor package 1a may be stably connected to the external substrate 900 through the solidified connection terminal 130.

Referring to FIG. 4E, by the reflow soldering, the semiconductor package 1a may be mounted on the external substrate 900, and the connection terminal 130 of the semiconductor package 1a may be coupled (e.g., soldered) to the substrate pad 910 of the external substrate 900.

As described above, during the reflow soldering, by applying (e.g., continuously applying) the external magnetic field, the package body PB1 of the semiconductor package 1a may maintain flat or substantially flat due to the force generated by the magnet 160 under the external magnetic field. Therefore, the high-temperature warpage of the semiconductor package 1a occurring during the reflow soldering may be corrected, thereby reducing or preventing the mismatch between the semiconductor package 1a and the external substrate 900 caused by the high-temperature warpage. As a result, the connection terminal 130 of the semiconductor package 1a may effectively contact and wet the substrate pad 910 of the external substrate 900 during the reflow soldering, such that electrical connection defects (e.g., non-soldering and virtual soldering) between the semiconductor package 1a and the external substrate 900 may be reduced or prevented.

As described above, since the magnet 160 includes the first magnet 161 and the second magnet 162 having different magnetic pole orientations, the warpage correction may be efficiently performed for the first portion R1 and the second portion R2 of the semiconductor package 1a having different warpage directions. For example, the first magnet 161 and the second magnet 162 having different magnetic pole orientations may apply the forces to the first portion R1 and the second portion R2 along directions opposite to or substantially opposite to the warpage directions of the first portion R1 and the second portion R2, respectively. Therefore, as compared with the case where a force is applied to the package body PB1 in a single direction, the displacement stroke of the first portion R1 and/or the second portion R2 during the recovery of the package body PB1 from the warpage state to a flat state may be effectively shortened. As such, the package body PB1 in which the high-temperature warpage occurs may be recovered to the flat state more quickly. On another hand, since the moving direction of the first portion R1 provided with the first magnet 161 and the moving direction of the second portion R2 provided with the second magnet 162 are substantially opposite under the external magnetic field, an average interval between the semiconductor package 1a and the external substrate 900 may not be substantially decreased or not excessively decreased (with respect to the average interval between the semiconductor package 1a and the external substrate 900 before the reflow soldering process is performed), as compared with the case of applying a force to the package body PB1 in a single direction. In particular, the second portion R2 of the semiconductor package 1a that has undergone the downward warpage toward the external substrate 900 may move away from the external substrate 900 by the force generated by the second magnet 162. As such, the lateral overflow of the melted connection terminal 130 may be reduced or prevented from occurring due to the excessive compression by the external force during the reflow soldering. As a result, the short connection between the connection terminals 130 caused by the lateral overflow of the melted connection terminals 130 may be prevented.

In the above, the surface mounting process of attaching the semiconductor package 1a according to some embodiments to the external substrate 900 has been described with reference to FIG. 4A through FIG. 4E, and it has been specifically described that the high-temperature warpage that has occurred in the package body PB1 of the semiconductor package 1a is corrected by applying the external magnetic field MF during the reflow soldering process, taken in conjunction with FIG. 4B through FIG. 4D. However, example embodiments are not limited thereto.

In some embodiments, the external magnetic field MF may be applied along with the application of the heat H, while starting to perform the reflow soldering. In this case, the force applied to the package body PB1 by the magnet 160 under the external magnetic field MF may be directly used to suppress or offset the warpage tendency of the package body PB1 generated due to the high temperature. Since the warpage tendency of the package body PB1 is suppressed from an initial stage of the reflow soldering, a warpage may not occur in the package body PB1 of the semiconductor package 1a during the entire reflow soldering, or only a minimal warpage may occur therein. As a result, the process time of performing the reflow soldering may be shortened, and other problems potentially caused by the occurrence of the warpage in the package body PB1 (for example, the fracture of the bonding wire 140 at the connection point, the delamination of the mold layer 150 from the connection member 100 and/or the semiconductor chip 120, the internal cracks occurring in the semiconductor chip 120 due to deformation, or the like) may be prevented.

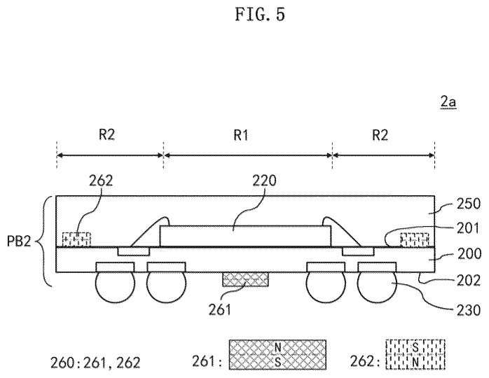

FIG. 5 is a cross-sectional view illustrating a semiconductor package according to one or more example embodiments. For Differences from the embodiments described with reference to FIG. 3A through FIG. 4E are mainly described below. In FIG. 5, the reference numerals similar to those in FIG. 3A through FIG. 4E denote similar components, and the repeated descriptions thereof may be omitted.

Referring to FIG. 5, a semiconductor package 2a according to some embodiments may include a package body PB2, a connection terminal 230, and a magnet 260. The package body PB2 may include a connection member 200 and a semiconductor chip 220. The connection member 200 may have a first surface (e.g., an upper or top surface) 201 and a second surface (e.g., a lower or bottom surface) 202 that are opposite to each other in a thickness direction (e.g., a vertical direction). In some embodiments, the connection member 200 may be a package substrate, such as a PCB or a multi-laminated substrate. The semiconductor chip 220 may be disposed on the first surface 201 of the connection member 200, and may be electrically connected to the connection member 200 by, for example, a bonding-wire method. The connection terminal 230 may be disposed on the second surface 202 of the connection member 200, electrically connected to the connection member 200, and electrically connected to the semiconductor chip 220 via the connection member 200.

In some embodiments, the package body PB2 of the semiconductor package 2a may include a first portion R1 and a second portion R2 in which warpages occur along different directions under a high-temperature condition. The specific profiles of the warpages of the first portion R1 and the second portion R2 of the package body PB2 may be similar to those described above with reference to FIG. 1 through FIG. 4E. In some embodiments, the first portion R1 of the package body PB2 may be a warped upward portion of the package body PB2 when the warpage occurs, while the second portion R2 of the package body PB2 may be a warped downward portion of the package body PB2 when the warpage occurs. For example, in FIG. 5, the first portion R1 may be a center portion of the package body PB2, and the second portion R2 may be an edge portion of the package body PB2. However, example embodiments are not limited thereto. As described above, the first portion R1 may be one or more portions of the package body PB2 becoming warped upward after warping as compared to before warping, and the second portion R2 may be one or more portions of the package body PB2 becoming warped downward after warping as compared to before warping.

In some embodiments, the magnet 260 of the semiconductor package 2a may be distributed in the package body PB2 and arranged to correspond to the profile of the warpage (e.g., a high-temperature warpage) of the package body PB2. The magnet 260 distributed in the package body PB2 may be configured to correct the warpage of the package body PB2, so as to enable the package body PB2 to recover from the warpage state into a flat or substantially flat state, or maintain a flat or substantially flat state.

As illustrated in FIG. 5, the magnet 260 may include a first magnet 261 and a second magnet 262.

The first magnet 261 may be disposed on the second surface 202 of the connection member 200 in the first portion R1 of the package body PB2, and configured to correct the warpage of the first portion R1 of the package body PB2. In some embodiments, the first magnet 261 may be attached and fixed to the second surface 202 of the connection member 200 by, for example, an adhesive or a tape. The first magnet 261 may be disposed between and surrounded by the connection terminals 230 on the second surface 202 of the connection member 200. However, example embodiments are not limited thereto.

The second magnet 262 may be disposed on the first surface 201 of the connection member 200 in the second portion R2 of the package body PB2, and configured to correct the warpage of the second portion R2 of the package body PB2. In some embodiments, the second magnet 262 may be attached and fixed to the first surface 201 of the connection member 200 by, for example, an adhesive or a tape. The second magnet 262 may be disposed around the semiconductor chip 220 on the first surface 201 of the connection member 200, with the semiconductor chip 220 located therebetween. However, example embodiments are not limited thereto.

As illustrated in FIG. 5, the first magnet 261 may be exposed to the outside on the second surface 202 of the connection member 200, and the second magnet 262 may be covered or encapsulated by the mold layer 250 of the semiconductor package 2a on the first surface 201 of the connection member 200. However, example embodiments are not limited thereto. For example, the first magnet 261 may also be surrounded or covered by an additional layer (e.g., an insulating layer, a passivation layer or a solder resist layer) further disposed at the second surface 202 of the connection member 200, and/or the second magnet 262 may also be exposed to the outside on the first surface 201 of the connection member 200. In some embodiments, the additional layer disposed at the second surface 202 of the connection member 200 may be included in the package body PB2 (e.g., the connection member 200), and constitute a portion of the package body PB2 (e.g., the connection member 200).

The magnet 260 (e.g., the first magnet 261 and the second magnet 262) may be substantially the same as or similar to the magnet 160 (e.g., the first magnet 161 and the second magnet 162) described with reference to FIG. 3A through FIG. 3C, respectively, and the method and principle of the magnet 260 (including the first magnet 261 and the second magnet 262) for correcting the warpage of the package body PB2 may be substantially the same as or similar to the method and principle of the magnet 160 (including the first magnet 161 and the second magnet 162) for correcting the warpage of the package body PB1 described with reference to FIG. 4A through FIG. 4E.

When the magnet 260 including the first magnet 261 and the second magnet 262 is distributed in the package body PB2 and arranged to correspond to the profile of the warpage of the semiconductor package 2a, while the semiconductor package 2a undergoes a high-temperature process (e.g. a reflow soldering), the first magnet 261 may apply a force to the first portion R1 of the package body PB2 under a magnetic field applied from the outside, thereby correcting the warpage of the first portion R1, and the second magnet 262 may apply a force to the second portion R2 of the package body PB2 under the magnetic field applied from the outside, thereby correcting the warpage of the second portion R2. Therefore, when undergoing the high-temperature process (e.g., the reflow soldering), the semiconductor package 2a (e.g., package body PB2) may maintain flat or substantially flat, such that electrical connection defects between the connection terminal 230 and the external substrate caused by the warpage of the semiconductor package 2a (e.g., package body PB2) may be reduced or prevented.

FIG. 6 is a bottom view illustrating a semiconductor package according to one or more example embodiments. Differences from embodiments described with reference to FIG. 5 are mainly described below. In FIG. 6, the reference numerals similar to those in FIG. 3A through FIG. 5 denote similar components, and the repeated descriptions thereof may be omitted.

According to FIG. 6, a semiconductor package 3a according to example embodiments may include a package body PB3 and a magnet 360. The package body PB3 may include a first portion R1 (e.g., a center portion illustrated in FIG. 6) and a second portion R2 (e.g., an edge portion illustrated in FIG. 6) that warp along different directions under a high-temperature condition. The magnet 360 may include a plurality of first magnets 361a and 361b and a plurality of second magnets 362.

Similar to the first magnet 261 described with reference to FIG. 5, the plurality of first magnets 361a and 361b may be disposed on a second surface (i.e., a bottom surface) of a connection member of the package body PB3 in the first portion R1 of the package body PB3, and configured to correct the warpage of the first portion R1 of the package body PB3. The plurality of first magnets 361a and 361b may be disposed between or among connection terminals 330 of the semiconductor package 3a, and surrounded by the connection terminals 330. At least one of the plurality of first magnets 361a and 361b may have a size (e.g., an area) different from sizes (e.g., areas) of others thereof. For example, in the view of FIG. 6, the first magnet 361b may have a larger area than that of the first magnet 361a. The first magnet 361b having a relatively large area may be disposed adjacent to a long side of the package body PB3 in the first portion R1 of the package body PB3. The first magnet 361a having a relatively small area may be disposed adjacent to a short side of the package body PB3 in the first portion R1 of the package body PB3.

Similar to the second magnet 262 described with reference to FIG. 5, the plurality of second magnets 362 may be disposed on a first surface (i.e., a top surface) of the connection member of the package body PB3 in the second portion R2 of the package body PB3, and configured to correct the warpage of the second portion R2 of the package body PB3. In some embodiments, the plurality of second magnets 362 may be disposed around a semiconductor chip on the top surface of the connection member of the package body PB3. For example, in the view of FIG. 6, the plurality of second magnets 362 may be disposed at four corners of the package body PB3, and the plurality of second magnets 362 may have substantially the same area.

Because the first magnets 361a and 361b and the second magnets 362 are respectively disposed on the surfaces of the connection member of the package body PB3, the sizes (e.g., the areas) and/or the numbers of the first magnets 361a and 361b and the second magnets 362 may be implemented in various ways. For example, as illustrated in FIG. 6, two second magnets 362 disposed at two corners of the second portion R2 along the long side of the package body PB3 may not be capable of efficiently applying the force to a center portion of the second portion R2 located at the long side of the package body PB3, due to a relatively large interval therebetween. When the first magnet 361b adjacent to the long side of the package body PB3 has a relatively large area, the forces applied by the first magnet 361b and the two second magnets 362 adjacent to the same long side of the package body PB3, respectively, to the package body PB3 may be more efficiently coupled. Therefore, a warpage of a portion of the package body PB3 located among the first magnet 361b and the two second magnets 362 (e.g., a triangle region adjacent to the long side of the package body PB3, which is constituted by the first magnet 361b and the two second magnets 362 as vertexes, in FIG. 6) may be more effectively corrected.

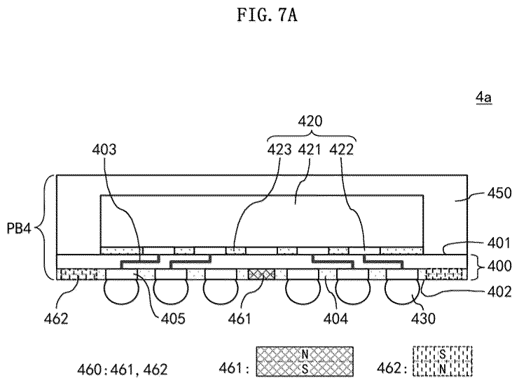

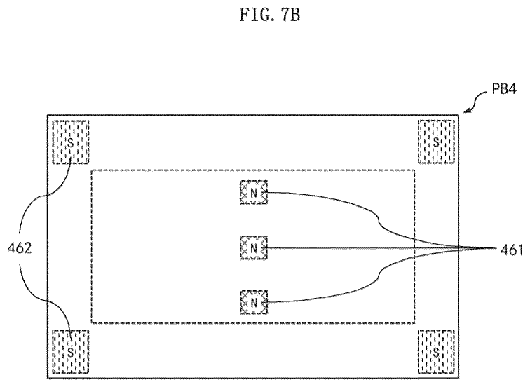

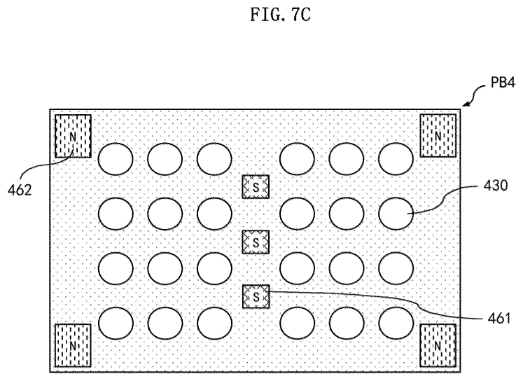

FIG. 7A is a cross-sectional view illustrating a semiconductor package according to one or more example embodiments. FIG. 7B is a top view illustrating a semiconductor package according to one or more example embodiments. FIG. 7C is a bottom view illustrating a semiconductor package according to one or more example embodiments. Differences from embodiments described with reference to FIG. 3A through FIG. 3C are mainly described below. In FIG. 7A through FIG. 7C, the reference numerals similar to those in FIG. 3A through FIG. 6 denote similar components, and the repeated descriptions thereof may be omitted.

Referring to FIG. 7A through FIG. 7C, a semiconductor package 4a may include a package body PB4, a connection terminal 430 and a magnet 460. The package body PB4 may include a connection member 400 and a semiconductor chip 420. The connection member 400 may include a first surface (e.g., an upper surface or a top surface) 401 and a second surface (e.g., a lower surface or a bottom surface) 402 opposite to each other in a thickness direction (e.g., a vertical direction). In some embodiments, the connection member 400 may be a redistribution structure (or a redistribution layer), which includes a plurality of wiring layers and a plurality of insulating layers alternately stacked on each other, and a plurality of vias connecting the plurality of wiring layers to each other in the plurality of insulating layers. The plurality of insulating layers may include an insulating material, and the plurality of wiring layers and the plurality of vias may include a conductive material such as a metal and a metal nitride. The plurality of wiring layers and vias connected to each other may constitute a plurality of internal conductive paths 403 in the connection member 400. As illustrated in FIG. 7A, the connection member 400 may include a lowermost insulating layer 404 exposed at the second surface 402 and a plurality of lower connection pads 405 disposed in the lowermost insulating layer 404. In some embodiments, each of the plurality of lower connection pads 405 may be a bump formed of a metal material. At least a portion of a lower surface of each of the plurality of lower connection pads 405 may be exposed at the second surface 402 of the connection member 400.

The semiconductor chip 420 may be disposed on the connection member 400. In some embodiments, the semiconductor chip 420 may be disposed on the first surface 401 of the connection member 400 by a flip-chip method. The semiconductor chip 420 may include a chip body 421, a chip pad 422 and a passivation film 423 disposed on a lower surface of the chip body 421. The chip pad 422 may be formed of a metal material. The passivation film 423 may be formed of an insulating material. The passivation film 423 may cover or at least partially cover the lower surface of the chip body 421, and expose at least a portion of a lower surface of the chip pad 422. The chip pad 422 may be disposed in the passivation film 423, and electrically connected to the chip body 421 (e.g., a circuit formed in the chip body 421). A surface of the chip body 421 provided with the chip pad 422 may be referred to as an active surface, and a surface of the semiconductor chip 420 provided with the chip pad 422 may also be referred to as an active surface. When the semiconductor chip 420 is provided by the flip-chip method, the active surface of the semiconductor chip 420 may face the first surface 401 of the connection member 400, and the chip pad 422 of the semiconductor chip 420 may be coupled to the connection member 400 (e.g., the wiring layer, the via, or optionally, a connection pad, exposed at the first surface 401 of the connection member 400). As such, the semiconductor chip 420 may be electrically connected to the connection member 400 through the chip pad 422, and electrically connected to the lower connection pad 405 of the connection member 400 through the internal conductive path 403 of the connection member 400. That is, the chip pad 422 of the semiconductor chip 420 may be fanned out to the lower connection pad 405 through the internal conductive path 403 of the connection member 400. In some embodiments, the semiconductor chip 420 may be provided in plural, and each of the plurality of semiconductor chips 420 may be electrically connected to the connection member 400 by the flip-chip method. For example, the plurality of semiconductor chips 420 may be disposed side by side or stacked vertically on the first surface 401 of the connection member 400. When the plurality of semiconductor chips 420 are stacked on each other on the connection member 400, the plurality of semiconductor chips 420 may be electrically connected to each other by a Through Silicon Via (TSV) method, but not limited thereto.

The connection terminal 430 may be disposed on the second surface 402 of the connection member 400. For example, a plurality of connection terminals 430 may be disposed on a plurality of lower connection pads 405 of the connection member 400 and connected to the plurality of lower connection pads 405, respectively. The connection terminal 430 may be electrically connected to the chip pad 422 of the semiconductor chip 420 through the lower connection pad 405 and the internal conductive path 403 of the connection member 400, and may be used to electrically connect the semiconductor package 4a to the outside. In some embodiments, the connection terminal 430 may include or may be a solder ball formed of solder. For example, the connection terminal 430 including the solder ball may be disposed in a form of a ball grid array (BGA) or a fine pitch BGA (FBGA).

In some embodiments, the package body PB4 of the semiconductor package 4a may further include a mold layer 450. The mold layer 450 may be disposed on the first surface 401 of the connection member 400. The mold layer 450 may cover or encapsulate the semiconductor chip 420 on the first surface 401 of the connection member 400. The mold layer 450 may include or may be formed of a molding material (e.g., epoxy molding compound (EMC)).

Referring to FIG. 7A through FIG. 7C, the magnet 460 of the semiconductor package 4a may be disposed in the lowermost insulating layer 404 of the connection member 400. For example, the magnet 460 may be embedded in the lowermost insulating layer 404 of the connection member 400. However, this is only an example. In some embodiments, the magnet 460 may be disposed or embedded in the lowermost insulating layer 404 of the connection member 400 and one or more insulating layers adjacent thereto. That is, the magnet 460 may be disposed or embedded in a lower portion of the connection member 400. In other words, the magnet 460 may be embedded on the second surface 402 of the connection member 400. In some embodiments, the magnet 460 may be formed by a deposition or damascene process using a magnetic material, during the process of forming (e.g., depositing) the plurality of wiring layers and insulating layers of the connection member 400. In some embodiments, the magnet 460 may also be formed by an etching process and a deposition or damascene process using a magnetic material after the connection member 400 is formed. In addition, the magnet 460 embedded in the connection member 400 may be electrically isolated or electrically insulated from the connection member 400. In some embodiments, similar to the semiconductor package 1a described with reference to FIG. 3A or the semiconductor package 2a described with reference to FIG. 5, in the semiconductor package 4a, the magnet 460 may be disposed or embedded inside the connection member 400, or may be disposed on the surface(s) (e.g., the first surface 401 and/or the second surface 402) of the connection member 400. When the magnet 460 is embedded inside the connection member 400, the magnet 460 may be formed by a deposition process using a magnetic material during the formation of the connection member 400. When the magnet 460 is disposed on the surface(s) of the connection member 400, the magnet 460 may be attached and fixed to the corresponding surface(s) of the connection member 400 by, for example, an adhesive or a tape.

In the semiconductor package 4a according to some embodiments, the magnet 460 may be distributed in the package body PB4 (e.g., the connection member 400) and arranged to correspond to a profile of a warpage which the package body PB4 has in warping, and configured to apply a force to the package body PB4 under an external magnetic field so as to correct the warpage of the package body PB4. For example, the magnet 460 may be configured to correct a high-temperature warpage or a tendency of high-temperature warpage of the package body PB4 when it undergoes a high-temperature process (e.g., reflow soldering). As illustrated in FIG. 7A through FIG. 7C, the magnet 460 may include a first magnet 461 and a second magnet 462. The first magnet 461 may be disposed in the connection member 400 and arranged to correspond to a warping of a first portion of the package body PB4 along a first direction, and configured to correct a warpage of the first portion of the package body PB4. The second magnet 462 may be disposed in the connection member 400 and arranged to correspond to a warping to a second portion of the package body PB4 along a second direction different from the first direction, and configured to correct a warpage of the second portion of the package body PB4. For example, during the high-temperature process (e.g., the reflow soldering), when an external magnetic field is applied to the semiconductor package 4a (e.g., the package body PB4), the first magnet 461 may apply a force to the first portion of the package body PB4 under the external magnetic field, and the second magnet 462 may apply a force to the second portion of the package body PB4 under the external magnetic field, thereby correcting the warpage of the package body PB4. As a result, when undergoing a high-temperature process such as reflow soldering, the semiconductor package 4a may maintain or recover into a flat or substantially flat profile. Therefore, it may be possible to reduce or prevent electrical connection defects (e.g., non-soldering, virtual soldering and/or short circuit) between the semiconductor package 4a and the external substrate caused by the warpage.

Alternatively or additionally, other features of the magnet 460, the first magnet 461 and the second magnet 462 described with reference to FIG. 7A through FIG. 7C except for the above features may be substantially the same as or similar to the features of one or more of the magnets 160, 260 and 360, the first magnets 161, 261, 361a and 361b, and the second magnets 162, 262 and 362 described with reference to FIG. 3A through FIG. 3C, FIG. 5 and FIG. 6, respectively.

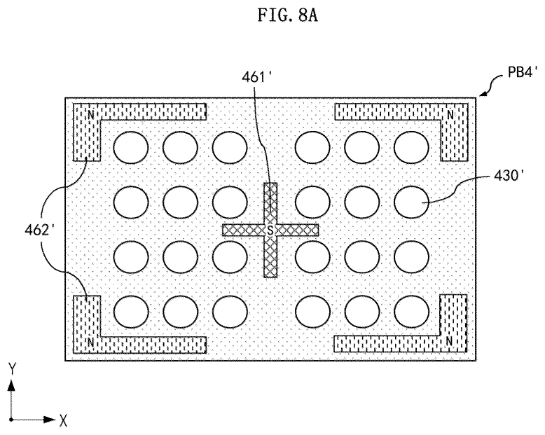

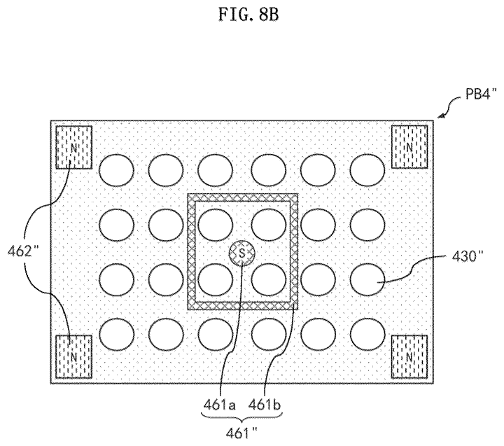

FIGS. 8A and 8B are bottom views illustrating a semiconductor package according to one or more example embodiments. Differences from embodiments described with reference to FIG. 7A through FIG. 7C are mainly described below. In FIGS. 8A and 8B, the reference numerals similar to those in FIG. 3A through FIG. 7C denote similar components, and the repeated descriptions thereof may be omitted.

Referring to FIG. 8A, unlike the plurality of rectangle-shaped first magnets 461 arranged side by side in the first portion (e.g., the center portion) of the package body PB4 described with reference to FIG. 7A through FIG. 7C, a first magnet 461′ disposed in a first portion (e.g., a center portion) of a package body PB4′ may have a cross shape. For example, the first magnet 461′ may have a center portion positioned between a plurality of connection terminals 430′ (e.g., in the center with respect to four connection terminals 430′), and arm portions respectively extending laterally from the center portion to a region between two adjacent connection terminals 430′. As such, while ensuring that the first magnet 461′ may effectively correct a warpage of the first portion of the package body PB4′, a more compact arrangement of the connection terminals 430′ may be allowed.

In addition, unlike the rectangle-shaped second magnets 462 described with reference to FIG. 7A through FIG. 7C, each of second magnets 462′ disposed in a second portion (e.g., an edge portion) of the package body PB4′ may have an L-shaped shape. For example, four second magnets 462′ may be disposed at four corners of the package body PB4′, respectively, and each second magnet 462′ may include a portion at one corner of the package body PB4′ and portions extending from the portion along the length (i.e., the X-direction) of the package body PB4′ and the width (i.e., the Y-direction) of the package body PB4′, and meeting to each other at the respective center of each second magnet 462′. The portion of each of the second magnets 462′ extending along the X-direction the package body PB4′ may be longer than the portion extending along the Y-direction of the package body PB4′, to form the L-shaped shape. As such, when an external magnetic field is applied to the package body PB4′, the second magnet 462′ may apply a force generated thereby under the external magnetic field more uniformly to the second portion of the package body PB4′. However, example embodiments are not limited thereto. For example, when the overall outline of the package body PB4′ is square-shaped, the portions of each second magnet 462′ extending along the sides of the package body PB4′ meeting each other may have the same size (e.g., length) as each other.

In some embodiments, the integral first magnet 461′ illustrated in FIG. 8A may be composed of a plurality of portions separated from each other, and/or the integral second magnet 462′ illustrated in FIG. 8A may be composed of a plurality of portions separated from each other. In this case, it may be more conducive to flexibly arrange the first magnet 461′ and the second magnet 462′ according to the warpage profile of the package body PB4′.

Referring to FIG. 8B, unlike the rectangle-shaped first magnets 461 distributed side by side in the first portion of the package body PB4 described with reference to FIG. 7A through FIG. 7C, a first magnet 461″ disposed in a first portion (e.g., a center portion) of a package body PB4″ may include a central magnet 461a and a peripheral magnet 461b. The central magnet 461a may be disposed at a region among a plurality of (e.g., four) adjacent connection terminals 430″, and may have a circular shape. The peripheral magnet 461b may be disposed in a rectangular frame shape at a periphery of the four adjacent connection terminals 430″, to surround the four adjacent connection terminals 430″ and the central magnet 461a therebetween. When the central magnet 461a has a circular shape, a projected area of the central magnet 461a in the region among the four adjacent connection terminals 430″ may be relatively large, which may allow efficient utilization of the limited region among the adjacent connection terminals 430″. When the peripheral magnet 461b is arranged in a rectangular frame shape, the utilization ratio of an edge region of the first portion of the package body PB4″ may be improved even if the connection terminals 430″ are densely arranged. In addition, in some embodiments, the rectangle frame-shaped peripheral magnet 461b illustrated in FIG. 8B may also have any suitable polygon shape that extends among the connection terminals 430″ according to the arrangement of the connection terminals 430″.

The first magnets 461′ and 461″ and the second magnets 462′ and 462″ described above with reference to FIGS. 8A and 8B are only examples, and example embodiments are not limited thereto. For example, each of the first and second magnets according to some embodiments may have various suitable shapes or any suitable combination of these shapes according to the available space/region of the package body of the semiconductor package for arranging the magnets, as long as the forces generated by the magnets under the external magnetic field may correct the warpage of the portion of the package body provided with the magnets.

In the above, some example embodiments have been described by taking the case where the package body of the semiconductor package has the high-temperature warpage profile in the convex curved-surface shape as an example. Below, the case where a package body of a semiconductor package has a high-temperature warpage profile in a complex undulation will be taken as an example to describe an example arrangement of magnets in a package body according to some embodiments.

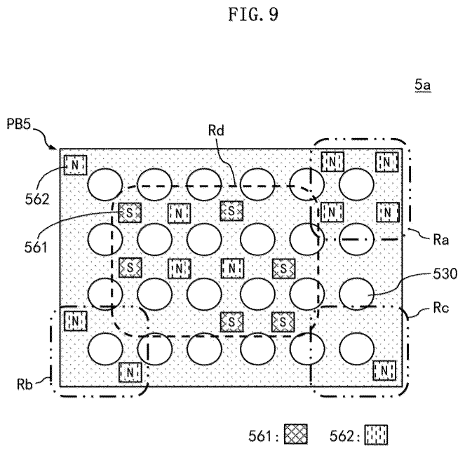

FIG. 9 is a bottom view illustrating a semiconductor package having a complex high-temperature warpage according to one or more example embodiments. The following description will be given by taking, as an example, a semiconductor package 5a having a configuration similar to that of the semiconductor package 4a described with reference to FIG. 7A through FIG. 7C, but it should be understood that the following description may be applied to the respective example embodiments described above.

Referring to FIG. 9, when undergoing a high-temperature process, a package body PB5 of the semiconductor package 5a may have a complex high-temperature warpage profile. For example, when the semiconductor package 5a is disposed on an external substrate and undergoes reflow soldering to be electrically connected with the external substrate, the package body PB5 may include a first portion Ra, a second portion Rb, a third portion Rc and a fourth portion Rd, of which profiles of high-temperature warpage are different from each other.

For example, the first portion Ra, the second portion Rb, and the third portion Rc of the package body PB5 may each have high-temperature warpages that are warped downward along directions toward the external substrate. A degree of the high-temperature warpage of the first portion Ra may be greater than that of the second portion Rb, and a degree of the high-temperature warpage of the second portion Rb may be greater than that of the third portion Rc.

For example, the fourth portion Rd of the package body PB5 may have a high-temperature warpage wave-shaped (e.g., in a three-dimensional space). In some embodiments, the fourth portion Rd of the package body PB5 may include a plurality of regions (or a plurality of portions) that are continuously distributed (e.g., contiguous to each other). A portion of the plurality of regions of the fourth portion Rd may have a high-temperature warpage (e.g., a first high-temperature warpage) along a first direction (e.g., warped upward away from the external substrate), and other portions (or remaining portions) of the plurality of regions of the fourth portion Rd may have a high-temperature warpage (e.g., a second high-temperature warpage) along a second direction (e.g., warped downward toward to the external substrate) different from the first direction. In the fourth portion Rd, the regions having the first high-temperature warpage and the regions having the second high-temperature warpage may be distributed alternatively and continuously with each other. For example, the region having the first high-temperature warpage of the fourth portion Rd may correspond to the first portion R1 described with reference to such as FIG. 7A through FIG. 7C, and the region having the second high-temperature warpage of the fourth portion Rd may correspond to the second portion R2 described with reference to such as FIG. 7A through FIG. 7C. In some embodiments, the plurality of regions having the first high-temperature warpage of the fourth portion Rd may have the same or different degrees of warpage as or from each other, and/or the plurality of regions having the second high-temperature warpage of the fourth portion Rd may have the same or different degrees of warpage as or from each other.

A first magnet 561 having a first magnetic pole orientation may be disposed in each of the plurality of regions of the fourth portion Rd that are warped upward. A second magnet 562 having a second magnetic pole orientation different from the first magnetic pole orientation may be disposed in each of the first portion Ra, the second portion Rb, the third portion Rc, and the plurality of regions of the fourth portion Rd that are warped downward.

As illustrated in FIG. 9, according to the difference in degree of high-temperature warpage, the number of the second magnets 562 included in the second portion Rb may be smaller than the number of the second magnets 562 included in the first portion Ra, and may be greater than the number of the second magnet 562 included in the third portion Rc. As such, under the same external magnetic field, a force applied to the second portion Rb by the second magnets 562 may be smaller than a force applied to the first portion Ra by the second magnets 562, and may be greater than a force applied to the third portion Rc by the second magnet 562. Therefore, the high-temperature warpages of the first portion Ra, the second portion Rb and the third portion Rc may be effectively and appropriately corrected. Although the case where the number of the magnets is positively correlated with the degree of high-temperature warpage of the package body is described herein as an example, this example is intended to explain that the magnitude of the force (e.g., the magnetic force) generated by the magnet under the external magnetic field is positively correlated with the degree of high-temperature warpage of the package body. For example, unlike that illustrated in FIG. 9, in the case where the first portion Ra, the second portion Rb and the third portion Rc include the same number of second magnets 562, the high-temperature warpages of the first portion Ra, the second portion Rb and the third portion Rc may be effectively and appropriately corrected by adjusting sizes (e.g., areas and/or volumes) and/or inherent magnetic fields of the second magnets 562 respectively included in the first portion Ra, the second portion Rb and the third portion Rc according to the difference in degree of high-temperature warpage. As a result, an effective and appropriate contact between the connection terminals 530 disposed at the first portion Ra, the second portion Rb and the third portion Rc of the package body PB5, and substrate pads of the external substrate may be ensured.

As illustrated in FIG. 9, since the fourth portion Rd of the package body PB5 may have a wave-shaped high-temperature warpage profile, a plurality of first magnets 561 and a plurality of second magnets 562 may be disposed in the fourth portion Rd of the package body PB5, to correct the wave-shaped high-temperature warpage of the fourth portion Rd. The plurality of first magnets 561 and the plurality of second magnets 562 may be distributed at positions corresponding to the peaks and the troughs of the wave-shaped profile of high-temperature warpage of the fourth portion Rd. For example, in the fourth portion Rd, the plurality of first magnets 561 may be respectively disposed at the plurality of peaks of the fourth portion Rd that are warped upward away from the external substrate, and the plurality of second magnets 562 may be respectively disposed at the plurality of troughs of the fourth portion Rd that are warped downward toward to the external substrate. Under the external magnetic field, the plurality of first magnets 561 and the plurality of second magnets 562 may each apply the forces to the fourth portion Rd of the package body PB5, such that the upwardly warped regions of the fourth portion Rd move downwardly (e.g., toward the external substrate), while the downwardly warped regions of the fourth portion Rd move upwardly (e.g., away from the external substrate). Therefore, the fourth portion Rd wave-shaped due to the high-temperature warpage may recover into a flat or substantially flat state under the common action of the plurality of first magnets 561 and the plurality of second magnets 562 arranged therein. In addition, because the plurality of regions of the fourth portion Rd having different warpage profiles move upwardly or downwardly at the same time, the fourth portion Rd may not shift upwardly or downwardly in its entirety, and therefore, the interval between the fourth portion Rd of the package body PB5 and the external substrate may be effectively maintained constant or substantially constant. As a result, an effective and appropriate contact between the connection terminals 530 disposed at the fourth portion Rd of the package body PB5 and the substrate pads of the external substrate may be ensured.

As a result, the complex warpage of the package body PB5 may be effectively corrected, and the efficiency of correcting the complex warpage of the package body PB5 may be improved. Therefore, electrical connection defects (e.g., non-soldering, virtual soldering, short circuit, etc.) between the semiconductor package 5a and the external substrate caused by the complex high-temperature warpage may be reduced or prevented.

As described herein, the warpage profile (e.g., high-temperature warpage profile) of the semiconductor package (e.g., due to high-temperature warping) may be obtained by a way of pre-simulation. For example, a semiconductor package that does not include a magnet may be prepared, and then the semiconductor package may be placed under a process condition corresponding to a high-temperature process expected to be performed, so as to observe the warpage profile of the semiconductor package. Herein, an image of the warped semiconductor package may be obtained by an optical imaging method, and then an image analysis software may be used to analyze the obtained image and draw a two-dimensional or three-dimensional topography (i.e., a warpage profile or a warpage outline) of the warped semiconductor package. After the warpage profile is obtained by the pre-simulation, the configuration (e.g., a position, a number, a shape, a size, an inherent magnetic field, and/or like) of a magnet distributed in a package body of the semiconductor package may be designed according to the warpage profile. In some embodiments, the configuration of the magnet may be designed according to the obtained warpage profile and a predetermined external magnetic field. Alternatively, after the configuration of the magnet is determined, an external magnetic field (e.g., a strength, an applying direction and/or a number thereof) required to correct the warpage of the package body may be designed according to the determined configuration of the magnet. Afterwards, a semiconductor package including a magnet may be prepared according to the design, a new pre-simulation may be performed on the semiconductor package including the magnet while the predetermined or designed external magnetic field may be applied during the new pre-simulation, and then the configuration of the magnet may be optimized according to the obtained warpage profile of the semiconductor package including the magnet. By repeating the above process once or more, the design of the semiconductor package including the magnet according to some embodiments may be completed. However, example embodiments are not limited thereto. For example, in some embodiments, the configuration of the magnet in the package body of the semiconductor package, and optionally, the external magnetic field required for the magnet, may be designed according to only the warpage profile obtained by the first pre-simulation. Afterwards, in the process of actually performing the high-temperature process of the semiconductor package, the occurrence and/or change of the warpage profile of the semiconductor package may be monitored by, for example, an optical imaging method, and the force (e.g., the magnitude of the force and/or the direction of the force) applied to the package body by the magnet in the semiconductor package may be controlled by dynamically adjusting the external magnetic field, thereby completing the warpage correction of the semiconductor package. Although it is generally described herein that the magnet applies the force to the semiconductor package under the external magnetic field to correct the warpage of the semiconductor package, it will be understood that the configuration of the magnet in the package body of the semiconductor package does not need to depend on a specific external magnetic field, but the external magnetic field to be applied may be variously adjusted according to the configuration of the magnet.

According to example embodiments, the semiconductor package may include the package body and the magnet, and the magnet may be distributed in the package body according to the warpage profile of the package body in warping. The external magnetic field may be applied to the package body during or after the high-temperature process (e.g., the reflow soldering process of coupling the semiconductor package to the external substrate). When the external magnetic field is applied, the magnet distributed in the package body may apply the force to the package body under the external magnetic field, to correct the warpage of the package body. Therefore, when undergoing the high-temperature process, the semiconductor package may be flat or substantially flat. Therefore, the electrical connection defects between the semiconductor package and the external substrate caused by the warpage may be reduced or prevented. Therefore, the semiconductor package having improved electrical connection with the external substrate may be provided.

In the semiconductor package according to example embodiments, the magnet distributed in the package body may include a plurality of magnets having different magnetic pole orientations, and the plurality of magnets having different magnetic pole orientations may be disposed in the package body and arranged to correspond to a plurality of portions of the package body having different warpage directions, respectively. Since the plurality of magnets have different magnetic pole orientations, when the same external magnetic field is applied, the plurality of magnets may apply forces, of which directions are opposite to the warpage directions of the plurality of portions of the package body, to these portions, respectively. As such, the forces applied to the package body by the magnets may be uniform in general, such that the semiconductor package after the warpage correction may be flat or substantially flat, and the interval between each portion of the semiconductor package and the external substrate may be uniform or substantially uniform. In addition, the plurality of portions of the package body having different warpage directions may be moved along directions opposite to the warpage directions by the force applied by the magnet, such that the displacement strokes required for the plurality of portions of the package body to recover from the warpage profile into a flat state may be reduced. Therefore, the semiconductor package may recover into a flat or substantially flat state more quickly, and the average interval between the semiconductor package after the warpage correction and the external substrate may be substantially unchanged or slightly changed as compared with the average interval between the semiconductor package without warpage and the external substrate. In particular, during the warpage correction, a portion of the package body warping toward the external substrate may move away from the external substrate by the force applied by the magnet, such that the lateral overflow of the connection terminal disposed between the portion of the package body and the external substrate due to excessive compression may be avoided. As a result, an effective and appropriate contact between the connection terminal of the semiconductor package and the substrate pad of the external substrate may be effectively ensured. Therefore, electrical connection problems, such as non-soldering, virtual soldering and/or short circuit, between the semiconductor package and the external substrate may be suppressed or reduced. Therefore, the semiconductor package having improved electrical connection with the external substrate may be provided.

In the semiconductor package according to example embodiments, the magnet may be flexibly distributed in any available space or region of the package body according to the warpage profile of the semiconductor package. Therefore, when the semiconductor package exhibits a complex warpage profile when undergoing the high temperature, the magnet arranged in the package body according to the warpage profile of the semiconductor package may effectively and appropriately correct the warpage of each portion of the semiconductor package, thereby efficiently suppressing or reducing electrical connection problems, such as non-soldering, virtual soldering and/or short circuit, between the semiconductor package having the complex warpage profile in warping and the external substrate. Therefore, the semiconductor package having improved electrical connection with the external substrate may be provided.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package comprising:
a package body comprising:
a connection member having a first surface and a second surface opposite the first surface; and
at least one semiconductor chip on the first surface of the connection member;
a connection terminal on the second surface of the connection member, and connected to the at least one semiconductor chip through the connection member; and
at least one magnet in the package body, the at least one magnet arranged to correspond to a warpage profile of the package body, and configured to correct warpage of the package body by applying a force to the package body in response to an external magnetic field applied to the semiconductor package.

2. The semiconductor package of claim 1, wherein the package body comprises a first portion having a first warpage along a first direction and a second portion having a second warpage along a second direction different from the first direction,
wherein the at least one magnet comprises a first magnet in the first portion of the package body and a second magnet in the second portion of the package body,
wherein the first magnet has a first magnetic pole orientation, and
wherein the second magnet has a second magnetic pole orientation different from the first magnetic pole orientation.

3. The semiconductor package of claim 2, wherein the first magnet is configured to apply a first force to the first portion of the package body in response to the external magnetic field being applied to the semiconductor package, the first force having a direction substantially opposite to the first direction, and
wherein the second magnet is configured to apply a second force to the second portion of the package body in response to the external magnetic field being applied to the semiconductor package, the second force having a direction substantially opposite to the second direction.

4. The semiconductor package of claim 2, wherein at least one of the first magnet and the second magnet comprises a plurality of portions spaced apart from each other.

5. The semiconductor package of claim 2, wherein the warpage profile of at least one of the first portion and the second portion is wave-shaped.

6. The semiconductor package of claim 1, wherein, based on the warpage of the package body occurring when the semiconductor package undergoes a reflow soldering, at least one magnet is configured to apply the force to the package body in response to the external magnetic field being applied to the semiconductor package during the reflow soldering.

7. The semiconductor package of claim 6, wherein the at least one magnet has a ferromagnetism, and
wherein the at least one magnet is further configured to maintain the ferromagnetism during the reflow soldering.

8. The semiconductor package of claim 1, wherein the connection member comprises a package substrate or a redistribution layer, and
wherein the at least one magnet is embedded in the connection member or is disposed on the first surface and the second surface of the connection member.

9. The semiconductor package of claim 1, wherein the at least one semiconductor chip is connected to the connection member by a bonding-wire method or a flip-chip method.

10. The semiconductor package of claim 1, further comprising a mold layer on the first surface of the connection member and encapsulating at least a portion of the at least one semiconductor chip.

11. A semiconductor package, comprising:
a package body comprising:
a connection member having a first surface and a second surface; and
at least one semiconductor chip on the first surface of the connection member;
at least one first magnet; and
at least one second magnet spaced apart from the at least one first magnet,
wherein, in response to an external magnetic field being applied to the package body, the at least one first magnet is configured to apply a first force to the package body in a first direction, and the at least one second magnet is configured to apply a second force to the package body in a second direction that is different from the first direction.

12. The semiconductor package of claim 11, wherein the at least one first magnet and the at least one second magnet are embedded within the connection member.

13. The semiconductor package of claim 11, wherein the at least one first magnet is provided on the second surface of the connection member, and
wherein the at least one second magnet is provided on the first surface of the connection member and is spaced apart from the at least one semiconductor chip.

14. The semiconductor package of claim 11, wherein the package body comprises:
a first portion within which the at least one semiconductor chip is provided and that warps downward in response to heat being applied to the package body, and
a second portion that warps downward in response to heat being applied to the package body,
wherein the first force applied by the at least one first magnet is configured to correct the upward warpage of the first portion, and
wherein the second force applied by the at least one second magnet is configured to correct the downward warpage of the second portion.

15. The semiconductor package of claim 11, wherein the connection member comprises a plurality of layers,
wherein a lowermost layer of the plurality of layers is an insulating layer, and
wherein the at least one first magnet and the at least one second magnet are embedded in the insulating layer.

16. The semiconductor package of claim 11, wherein the at least one first magnet is provided within a perimeter defined by the at least one semiconductor chip.

17. The semiconductor package of claim 16, wherein the at least one second magnet is provided outside of the perimeter defined by the at least one semiconductor chip.

18. The semiconductor package of claim 11, further comprising a plurality of connection terminals on the second surface of the connection member,
wherein the at least one first magnet and the at least one second magnet are provided so as to not vertically overlap with the plurality of connection terminals.

19. The semiconductor package of claim 11, further comprising a plurality of connection terminals on the second surface of the connection member,
wherein the at least one first magnet is provided between the plurality of connection terminals.

20. A method, comprising:
providing a semiconductor package, the semiconductor package comprising:
a package body comprising a connection member having a first surface and a second surface, and at least one semiconductor chip on the first surface of the connection member;
at least one connection terminal on the second surface of the connection member; and
at least one magnet in the package body;
aligning the at least one connection terminal with at least one substrate pad of an external substrate;
applying heat to the semiconductor package; and
correcting warpage of the package body by applying an external magnetic force to the semiconductor package that causes the at least one magnet in the package body to apply a force to the package body in a direction that is opposite to a direction of the warpage.
